(19) United States
(12) Patent Application Publication
(10) Pub. No.: US 2025/0132253 A1
(43) Pub. Date: Apr. 24, 2025

(54) SEMICONDUCTOR MEMORY DEVICE

(71) Applicant: Samsung Electronics Co., Ltd., Suwon-si (KR)

(72) Inventors: Taejin PARK, Suwon-si (KR); Hyeonkyu LEE, Suwon-si (KR); Sungsoo YIM, Suwon-si (KR)

(73) Assignee: Samsung Electronics Co., Ltd., Suwon-si (KR)

(21) Appl. No.: 18/625,341

(22) Filed: Apr. 3, 2024

(30) Foreign Application Priority Data
Oct. 18, 2023 (KR) 10-2023-0139876

(51) Int. Cl. H01L 23/528; H10B 12/00

(52) U.S. Cl. CPC H01L 23/5283; H10B 12/315; H10B 12/488

(57) ABSTRACT

A semiconductor memory device includes a conductive line extending in a first direction, first and second channel regions connected to the conductive line, contact plugs apart from the conductive line in a vertical direction with the first and second channel regions therebetween, a back gate electrode extending in a second direction perpendicular to the first direction between the first and second channel regions, and a back gate dielectric film covering surfaces of the back gate electrode, wherein the back gate dielectric film includes a vertical extension portion arranged between the back gate electrode and each of the first and second channel regions to cover sidewalls of the back gate electrode, and a horizontal extension portion connected integrally to the vertical extension portion and covering the back gate electrode at one position selected from a first position facing the conductive line and a second position facing the contact plugs.

### CROSS-REFERENCE TO RELATED APPLICATION

This application is based on and claims priority under 35 U.S.C. § 119 to Korean Patent Application No. 10-2023-0139876, filed on Oct. 18, 2023, in the Korean Intellectual Property Office, the disclosure of which is incorporated by reference herein in its entirety.

### BACKGROUND

The inventive concepts relate to semiconductor memory devices, and more particularly, to semiconductor memory devices including a vertical channel transistor.

Recently, advances in electronics technology have led to the rapid down-scaling of semiconductor devices. Accordingly, memory cells are required to be finer-sized, and thus, there is a limit in maintaining higher degrees of integration and reliability in existing memory cells. Therefore, there is a need to develop a semiconductor memory device with a structure that facilitate the fabrication of memory cells having finer sizes and higher degrees of integration.

### SUMMARY

Some example embodiments of the inventive concepts provide semiconductor memory devices having a structure capable of mitigating or preventing process defects, such as the formation of unintended voids or seams or nonuniform thicknesses of components required (or alternatively, desired) to form a vertical channel transistor, during the process of forming the components, and facilitating the down-scaling and higher integration of memory cells, even when the components required (or alternatively, desired) to form a vertical channel transistor are arranged in a relatively narrow and long space due to the down-scaling and higher integration.

According to an aspect of the inventive concepts, a semiconductor memory device may include a conductive line extending lengthwise in a first horizontal direction, first and second channel regions over the conductive line and apart from each other in the first horizontal direction, each of the first and second channel regions configured to be connected to the conductive line, a plurality of contact plugs apart from the conductive line in a vertical direction with the first and second channel regions therebetween, the plurality of contact plugs aligned in the first horizontal direction, a back gate electrode extending lengthwise in a second horizontal direction between the first and second channel regions, the back gate electrode being apart from the conductive line and each of the plurality of contact plugs in the vertical direction, the second horizontal direction being perpendicular to the first horizontal direction, and a back gate dielectric film covering surfaces of the back gate electrode, wherein the back gate dielectric film includes a vertical extension portion and a horizontal extension portion, the vertical extension portion being between the back gate electrode and the first channel region and between the back gate electrode and the second channel region and covering sidewalls of the back gate electrode, the horizontal extension portion integrally connected to the vertical extension portion and covering an end surface of the back gate electrode at one position selected from a first position facing the conductive line and a second position facing the plurality of contact plugs.

According to another aspect of the inventive concepts, a semiconductor memory device may include a conductive line extending lengthwise in a first horizontal direction, a plurality of channel regions over the conductive line and apart from each other in the first horizontal direction, each of the plurality of channel regions configured to be connected to the conductive line, a plurality of contact plugs apart from the conductive line in a vertical direction with the plurality of channel regions therebetween, the plurality of contact plugs aligned in the first horizontal direction, a back gate electrode apart from the conductive line and each of the plurality of contact plugs in the vertical direction, the back gate electrode extending lengthwise in a second horizontal direction between first and second channel regions, the first and second channel regions being two adjacent channel regions selected from the plurality of channel regions, the second horizontal direction being perpendicular to the first horizontal direction, a first word line apart from the back gate electrode in the first horizontal direction with the first channel region therebetween, a second word line apart from the back gate electrode in the first horizontal direction with the second channel region therebetween, and a back gate dielectric film covering surfaces of the back gate electrode, wherein the back gate dielectric film includes a vertical extension portion and a horizontal extension portion, the vertical extension portion between the back gate electrode and the first channel region and between the back gate electrode and the second channel region and covering sidewalls of the back gate electrode, the horizontal extension portion integrally connected to the vertical extension portion and covering an end surface of the back gate electrode at one position selected from a first position facing the conductive line and a second position facing the plurality of contact plugs.

According to another aspect of the inventive concepts, a semiconductor memory device may include a plurality of conductive lines extending lengthwise in a first horizontal direction and being apart from each other in a second horizontal direction, the second horizontal direction being perpendicular to the first horizontal direction, a plurality of contact plugs apart from the plurality of conductive lines in a vertical direction, a plurality of channel regions between the plurality of conductive lines and the plurality of contact plugs, each of the plurality of channel regions including one end connected to one conductive line from among the plurality of conductive lines and another end connected to one contact plug selected from the plurality of contact plugs, a plurality of back gate electrodes apart from each other in the first horizontal direction and extending lengthwise in the second horizontal direction between the plurality of conductive lines and the plurality of contact plugs, a plurality of back gate dielectric films covering surfaces of the plurality of back gate electrodes, respectively, each of the plurality of back gate dielectric films being in contact with one back gate electrode selected from the plurality of back gate electrodes and with a pair of channel regions adjacent to the one back gate electrode, and a plurality of word lines extending lengthwise in the second horizontal direction and between the plurality of conductive lines and the plurality of contact plugs, wherein the plurality of word lines are arranged such that each pair of adjacent word lines selected from the plurality of word lines are between a pair of back gate electrodes selected from among the plurality of back gate electrodes, and each of the plurality of back gate dielectric films includes a vertical extension portion and a horizontal extension portion, the vertical extension portion covering sidewalls of a corresponding back gate electrode selected from the plurality of back gate electrodes, the horizontal extension portion integrally connected to the vertical extension portion and covering an end surface of the corresponding back gate electrode at one position selected from a first position facing the plurality of conductive lines and a second position facing the plurality of contact plugs.

### BRIEF DESCRIPTION OF THE DRAWINGS

Example embodiments will be more clearly understood from the following detailed description taken in conjunction with the accompanying drawings in which:

FIG. 1 is a planar layout diagram illustrating some components of a semiconductor memory device according to an example embodiment;

FIG. 2 is a cross-sectional view of the semiconductor memory device of FIG. 1, taken along a line X1-X1′ of FIG. 1;

FIG. 3 is an enlarged cross-sectional view of a region EX1 of FIG. 2;

FIGS. 4 to 10 are cross-sectional views each illustrating a semiconductor memory device according to some example embodiments;

FIGS. 11A to 30 are diagrams respectively illustrating a sequence of processes of a method of fabricating a semiconductor memory device according to an example embodiment, and in particular, FIGS. 11A, 12A, 13A, 14A, 15A, 16A, 17A, 19A, 22A, 23A, and 27A are planar layout diagrams each illustrating some components of the semiconductor memory device according to the sequence of processes to describe the method of fabricating the semiconductor memory device, and FIGS. 11B, 12B, 13B, 14B, 15B, 16B, 17B, 18, 19B, 20, 21, 22B, 23B, 24, 25, 26, 27B, 28, 29, and 30 are cross-sectional views each illustrating a portion of the semiconductor memory device, which corresponds to the cross-section taken along the line X1-X1′ in FIG. 1, according to the sequence of processes;

FIG. 31 is a cross-sectional view illustrating a method of fabricating a semiconductor memory device, according to an example embodiment;

FIGS. 32 and 33 are cross-sectional views illustrating a method of fabricating a semiconductor memory device, according to an example embodiment; and

FIGS. 34 and 35 are cross-sectional views illustrating a method of fabricating a semiconductor memory device, according to an example embodiment.

### DETAILED DESCRIPTION

Hereinafter, some example embodiments of the inventive concepts will be described in detail with reference to the accompanying drawings. Like components are denoted by like reference numerals throughout the specification, and repeated descriptions thereof are omitted.

It should be understood that, although the terms such as “first”, “second”, “third” and the like are used herein to describe various components, these components are not limited by these terms. These terms are used only to distinguish one component from another component, and it is a matter of course that a first component could be termed a second component or a third component and vice versa unless clearly stated otherwise. For example, a first channel region may be referred to as a second channel region or a third channel region without departing from the scope of the inventive concepts, and similarly, a second channel region or a third channel region may be referred to as a first channel region. Although a first channel region, a second channel region, and a third channel region are each a channel region, the first channel region, the second channel region, and the third channel region are not the same channel region.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “at least one of,” when preceding a list of elements, modify the entire list of elements and do not modify the individual elements of the list. Thus, for example, both “at least one of A, B, or C,” “at least one of A, B, and C,” and “at least one selected from A, B and C” mean either A, B, C or any combination thereof. Likewise, A and/or B means A, B, or A and B.

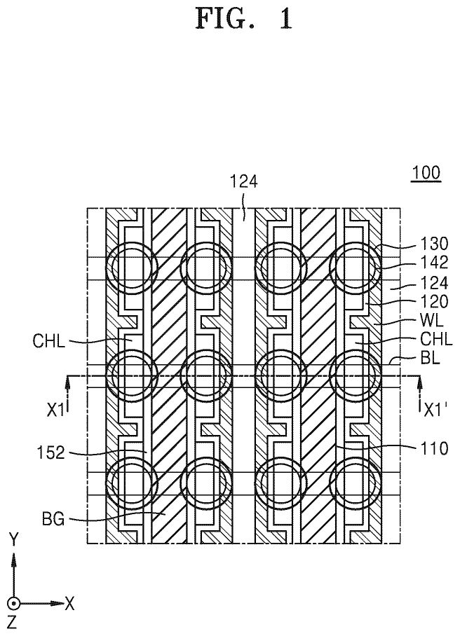

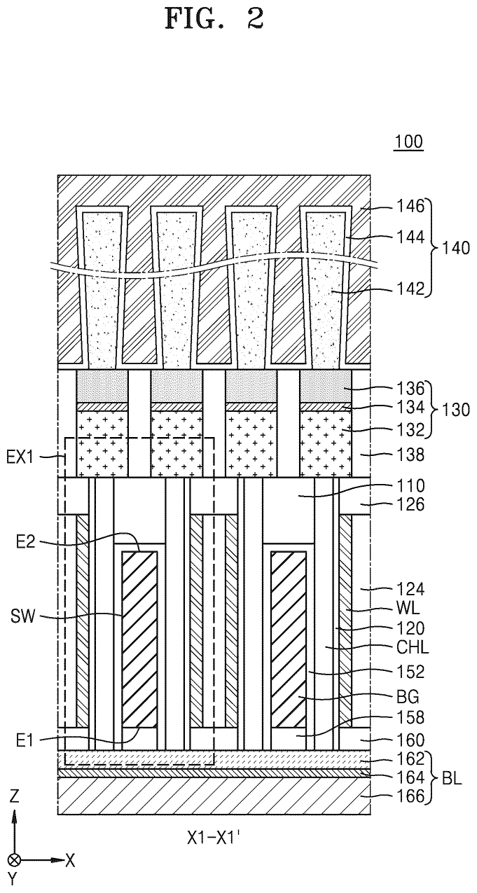

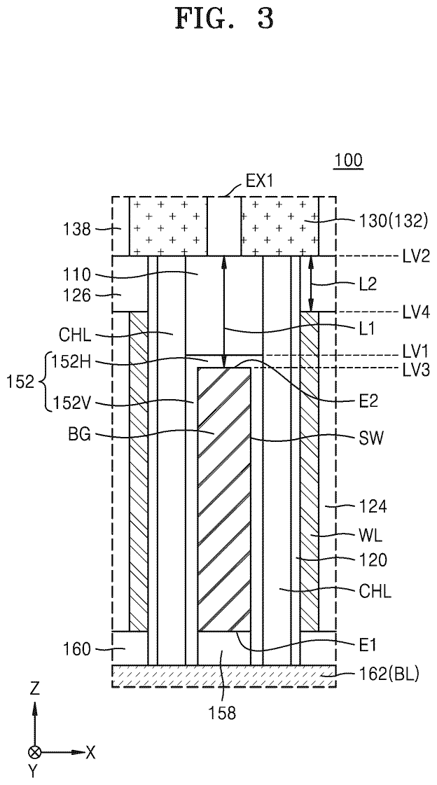

FIG. 1 is a planar layout diagram illustrating some components of a semiconductor memory device 100 according to an example embodiment. FIG. 2 is a cross-sectional view of the semiconductor memory device 100, taken along a line X1-X1′ of FIG. 1, and FIG. 3 is an enlarged cross-sectional view of a region EX1 of FIG. 2.

Referring to FIGS. 1 to 3, the semiconductor memory device 100 may include a plurality of conductive lines BL extending lengthwise in a first horizontal direction (X direction) and repeatedly arranged apart from each other in a second horizontal direction (Y direction) that is perpendicular to the first horizontal direction (X direction). In the semiconductor memory device 100, each of the plurality of conductive lines BL may constitute a bit line.

A plurality of channel regions CHL may be arranged over each of the plurality of conductive lines BL, and a plurality of contact plugs 130 may be arranged on the plurality of channel regions CHL, respectively. The plurality of channel regions CHL may be repeatedly arranged between the plurality of conductive lines BL and the plurality of contact plugs 130 and may be apart from each other in the first horizontal direction (X direction) and the second horizontal direction (Y direction). Each of the plurality of channel regions CHL may have one end, which is connected to one conductive line BL selected from the plurality of conductive lines BL, and another end, which is connected to one contact plug 130 selected from the plurality of contact plugs 130. Each of the plurality of channel regions CHL may be in contact with one conductive line BL and one contact plug 130.

Each of the plurality of conductive lines BL may include metal, conductive metal nitride, metal silicide, doped polysilicon, or a combination thereof. For example, each of the plurality of conductive lines BL may include Ti, TiN, Ta, TaN, Mo, Ru, W, WN, Co, Ni, TiSi, TiSiN, WSi, WSiN, TaSi, TaSiN, RuTiN, CoSi, NiSi, doped polysilicon, or a combination thereof. In some example embodiments, each of the plurality of conductive lines BL may include a first conductive line 162, a second conductive line 164, and a third conductive line 166, which are sequentially stacked in the stated order on the plurality of channel regions CHL, as shown in FIG. 2. For example, although the first conductive line 162 may include doped polysilicon, the second conductive line 164 may include metal silicide, and the third conductive line 166 may include metal, the inventive concepts are not limited thereto.

The plurality of contact plugs 130 may be apart from the plurality of conductive lines BL in the vertical direction (Z direction) with the plurality of channel regions CHL therebetween. The plurality of contact plugs 130 may be arranged in a matrix to be apart from each other in the first horizontal direction (X direction) and the second horizontal direction (Y direction). The plurality of contact plugs 130 may be respectively connected to the plurality of channel regions CHL in one-to-one correspondence.

Each of the plurality of contact plugs 130 may include metal, conductive metal nitride, metal silicide, doped polysilicon, or a combination thereof. For example, each of the plurality of contact plugs 130 may include Ti, TiN, Ta, TaN, Mo, Ru, W, WN, Co, Ni, TiSi, TiSiN, WSi, WSIN, TaSi, TaSiN, RuTiN, CoSi, NiSi, doped polysilicon, or a combination thereof. In some example embodiments, each of the plurality of contact plugs 130 may include a first conductive pattern 132, a second conductive pattern 134, and a third conductive pattern 136, which are sequentially stacked in the stated order on each of the plurality of channel regions CHL, as shown in FIG. 2. For example, although the first conductive pattern 132 may include doped polysilicon, the second conductive pattern 134 may include metal silicide, and the third conductive pattern 136 may include metal, the inventive concepts are not limited thereto.

As shown in FIG. 1, the plurality of channel regions CHL may include a first group of channel regions CHL, which are arranged in a line in the first horizontal direction (X direction) and being apart from each other in the first horizontal direction (X direction), and a second group of channel regions CHL, which are arranged in a line in the second horizontal direction (Y direction) and being apart from each other in the second horizontal direction (Y direction). Each of the plurality of contact plugs 130 may be arranged on one channel region CHL selected from the plurality of channel regions CHL. Each of the plurality of contact plugs 130 may pass through an interlayer dielectric 138 to contact the selected one channel region CHL. The interlayer dielectric 138 may include a silicon oxide film, a silicon nitride film, or a combination thereof.

In some example embodiments, each of the plurality of channel regions CHL may include silicon, for example, single-crystal silicon, polycrystalline silicon, or amorphous silicon. In some example embodiments, each of the plurality of channel regions CHL may include at least one selected from Ge, SiGe, SiC, GaAs, InAs, and InP. In some example embodiments, the channel region CHL may include a conductive region, for example, an impurity-doped well or an impurity-doped structure.

A plurality of back gate electrodes BG and a plurality of word lines WL may be arranged over each of the plurality of conductive lines BL. The plurality of back gate electrodes BG and the plurality of word lines WL may each extend lengthwise in the second horizontal direction (Y direction) vertically between the plurality of conductive lines BL and the plurality of contact plugs 130. The plurality of back gate electrodes BG may be apart from each other in the first horizontal direction (X direction) and the plurality of word lines WL may be apart from each other in the first horizontal direction (X direction).

In the plurality of back gate electrodes BG and the plurality of word lines WL, which are arranged in a line in the first horizontal direction (X direction) over one conductive line BL, one back gate electrode BG and a pair of word lines WL may be alternately arranged, and the one back gate electrode BG may be apart from the pair of word lines WL with one channel region CHL therebetween. That is, the plurality of word lines WL may be arranged such that a pair of adjacent word lines WL are arranged between a pair of adjacent back gate electrodes BG.

Each of the plurality of back gate electrodes BG may include metal, conductive metal nitride, doped polysilicon, or a combination thereof. For example, each of the plurality of back gate electrodes BG may include, but is not limited to, Ti, TiN, Ta, TaN, Mo, Ru, W, WN, TiSiN, WSiN, doped polysilicon, or a combination thereof. Each of the plurality of word lines WL may include metal, conductive metal nitride, or a combination thereof. For example, each of the plurality of word lines WL may include, but is not limited to, Ti, TiN, Ta, TaN, Mo, Ru, W, WN, TiSiN, WSiN, or a combination thereof.

Each of the plurality of back gate electrodes BG may extend lengthwise in the second horizontal direction (Y direction) between two channel regions CHL that are adjacent to each other in the first horizontal direction (X direction). Each of the plurality of back gate electrodes BG may be arranged to be apart from the conductive line BL and each of the plurality of contact plugs 130 in the vertical direction (Z direction). As shown in FIG. 2, each of the plurality of back gate electrodes BG may have a pair of sidewalls SW facing the channel region CHL, a first end surface E1 facing the conductive line BL, and a second end surface E2 facing the plurality of contact plugs 130.

The semiconductor memory device 100 may include a plurality of back gate dielectric films 152 respectively covering the surfaces of the plurality of back gate electrodes BG. Each of the plurality of back gate dielectric films 152 may be arranged between a back gate electrode BG and a pair of channel regions CHL that are arranged adjacent to both sides of the back gate electrode BG with the back gate electrode BG therebetween. Each of the plurality of back gate dielectric films 152 may be in contact with the pair of channel regions CHL. A back gate dielectric film 152 may be arranged between a pair of adjacent channel regions CHL to cover the sidewall SW, the first end surface E1, and the second end surface E2 of the back gate electrode BG. The back gate dielectric film 152 may be in contact with each of the sidewall SW, the first end surface E1, and the second end surface E2 of the back gate electrode BG.

The back gate dielectric film 152 may include a vertical extension portion 152V, which is arranged between the back gate electrode BG and the channel region CHL adjacent thereto to cover the sidewall SW of the back gate electrode BG, and a horizontal extension portion 152H covering the second end surface E2 of the back gate electrode BG, which faces the plurality of contact plugs 130. The vertical extension portion 152V and the horizontal extension portion 152H of the back gate dielectric film 152 may have structures integrally connected to each other. The back gate dielectric film 152 may have a U-like cross-sectional shape, which is open toward the conductive line BL, in a cross-sectional view taken in the first horizontal direction (X direction). The vertical extension portion 152V of the back gate dielectric film 152 may be in contact with the sidewall SW of the back gate electrode BG and with the conductive line BL, and the horizontal extension portion 152H of the back gate dielectric film 152 may be in contact with the second end surface E2 of the back gate electrode BG, which faces the plurality of contact plugs 130.

In a region between a pair of adjacent channel regions CHL, a first capping insulating pattern 110 may be arranged between the horizontal extension portion 152H of the back gate dielectric film 152 and the plurality of contact plugs 130. In a region between a pair of adjacent channel regions CHL, a second capping insulating pattern 158 may be arranged between the back gate electrode BG and the conductive line BL. The first capping insulating pattern 110, the back gate electrode BG, and the second capping insulating pattern 158 may be arranged to overlap each other in the vertical direction (Z direction).

Each of the first capping insulating pattern 110 and the second capping insulating pattern 158 may include a silicon oxide film, a silicon nitride film, or a combination thereof.

In some example embodiments, the first capping insulating pattern 110 and the second capping insulating pattern 158 may include different materials, respectively. For example, the first capping insulating pattern 110 may include a silicon oxide film and the second capping insulating pattern 158 may include a silicon nitride film. In some example embodiments, the first capping insulating pattern 110 and the second capping insulating pattern 158 may include the same material. For example, the first capping insulating pattern 110 and the second capping insulating pattern 158 may include the same material selected from a silicon oxide film and a silicon nitride film.

The horizontal extension portion 152H of the back gate dielectric film 152 may be arranged between the back gate electrode BG and the first capping insulating pattern 110 and may be in contact with each of the back gate electrode BG and the first capping insulating pattern 110. The closest portion of the back gate dielectric film 152 to the plurality of contact plugs 130 may correspond to the horizontal extension portion 152H, and the horizontal extension portion 152H of the back gate dielectric film 152 may be apart from the plurality of contact plugs 130 in the vertical direction (Z direction) with the first capping insulating pattern 110 therebetween. The vertical extension portion 152V of the back gate dielectric film 152 may be in contact with each of a pair of channel regions CHL, which are respectively arranged on both sides of the back gate electrode BG to be adjacent to each other, and the horizontal extension portion 152H of the back gate dielectric film 152 may be arranged apart from, in the vertical direction (Z direction), a pair of contact plugs 130 that are connected to the pair of channel regions CHL, respectively.

In the vertical direction (Z direction), the length of the back gate dielectric film 152 may be greater than the length of the back gate electrode BG. The vertical extension portion 152V of the back gate dielectric film 152 may be arranged between the second capping insulating pattern 158 and the channel region CHL. The farthest end of the vertical extension portion 152V of the back gate dielectric film 152 from the back gate electrode BG may be in contact with the conductive line BL.

Each of the plurality of word lines WL may be arranged apart from the conductive line BL and each of the plurality of contact plugs 130 in the vertical direction (Z direction). In the first horizontal direction (X direction), a pair of word lines WL may be arranged between each of the plurality of back gate electrodes BG. The pair of word lines WL may be apart from the back gate electrode BG adjacent thereto in the first horizontal direction (X direction) with one channel region CHL therebetween.

As shown in FIG. 3, a vertical level LV1 of the farthest portion of the back gate dielectric film 152 from the conductive line BL in the vertical direction (Z direction) may be closer to the conductive line BL than a vertical level LV2 of the closest portion of the plurality of contact plugs 130 to the conductive line BL in the vertical direction (Z direction). A vertical level LV3 of the second end surface E2 of the back gate electrode BG may be closer to the conductive line BL than a vertical level LV4 of the farthest end of the word line WL from the conductive line BL. A first vertical distance L1 from the plurality of contact plugs 130 to the second end surface E2 of the back gate electrode BG may be greater than a second vertical distance L2 from the plurality of contact plugs 130 to the word line WL. In the vertical direction (Z direction), the length of the first capping insulating pattern 110 may be greater than the length of a first gap-fill insulating pattern 126.

An isolation insulating pattern 124 may be arranged between a pair of word lines WL, which are arranged between a pair of adjacent channel regions CHL. The first gap-fill insulating pattern 126 may be arranged between the pair of word lines WL and the plurality of contact plugs 130, and a second gap-fill insulating pattern 160 may be arranged between the pair of word lines WL and the conductive line BL. The pair of word lines WL, the first gap-fill insulating pattern 126, and the second gap-fill insulating pattern 160 may be arranged between the pair of adjacent channel regions CHL to overlap each other in the vertical direction (Z direction). The pair of word lines WL may be apart from the plurality of contact plugs 130 in the vertical direction (Z direction) with the first gap-fill insulating pattern 126 therebetween. The pair of word lines WL may be apart from the conductive line BL with the second gap-fill insulating pattern 160 therebetween. In the vertical direction (Z direction), the length of the second capping insulating pattern 158 may be equal or similar to the length of the second gap-fill insulating pattern 160.

Each of the isolation insulating pattern 124, the first gap-fill insulating pattern 126, and the second gap-fill insulating pattern 160 may include a silicon oxide film, a silicon nitride film, or a combination thereof. In some example embodiments, the isolation insulating pattern 124, the first gap-fill insulating pattern 126, and the second gap-fill insulating pattern 160 may respectively include materials that are identical or similar to each other. In some example embodiments, at least one of the isolation insulating pattern 124, the first gap-fill insulating pattern 126, and the second gap-fill insulating pattern 160 may include a different material from the others. For example, each of the isolation insulating pattern 124, the first gap-fill insulating pattern 126, and the second gap-fill insulating pattern 160 may include, but is not limited to, a silicon nitride film.

A gate dielectric film 120 may be arranged between each of the plurality of word lines WL and the channel region CHL adjacent thereto. A pair of gate dielectric films 120 may be arranged between a pair of adjacent channel regions CHL, and a pair of word lines WL may be arranged between the pair of gate dielectric films 120. Herein, a gate dielectric film 120 located on one side in the first horizontal direction (X direction), out of the pair of gate dielectric films 120, may be referred to as a first gate dielectric film, and a gate dielectric film 120 located on the other side in the first horizontal direction (X direction) may be referred to as a second gate dielectric film. Each of the pair of gate dielectric films 120 may include one end, which is in contact with the conductive line BL, and another end, which is in contact with one contact plug 130 selected from the plurality of contact plugs 130.

In some example embodiments, each of the gate dielectric film 120 and the back gate dielectric film 152 may include a silicon oxide film, a high-K film, or a combination thereof. The high-K film refers to a film having a dielectric constant which is higher than that of a silicon oxide film. In some example embodiments, each of the gate dielectric film 120 and the back gate dielectric film 152 may include at least one material selected from silicon oxide, hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO)), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO), and lead scandium tantalum oxide (PbScTaO).

The plurality of back gate electrodes BG, the plurality of word lines WL, the plurality of channel regions CHL, the plurality of back gate dielectric films 152, and the plurality of gate dielectric films 120, which are arranged between the plurality of conductive lines BL and the plurality of contact plugs 130, may constitute a plurality of vertical channel transistors.

As shown in FIGS. 1 and 2, a capacitor structure 140 may be arranged on the plurality of contact plugs 130 and the interlayer dielectric 138. The capacitor structure 140 may include a plurality of lower electrodes 142, a capacitor dielectric film 144 conformally covering the surface of each of the plurality of lower electrodes 142, and an upper electrode 146 covering the capacitor dielectric film 144. Each of the plurality of lower electrodes 142 may be connected to the channel region CHL via one contact plug 130 selected from the plurality of contact plugs 130. The third conductive pattern 136 of each of the plurality of contact plugs 130 may function as a landing pad with which one lower electrode 142 selected from the plurality of lower electrodes 142 is in contact.

According to the semiconductor memory device 100 described with reference to FIGS. 1 to 3, even when components required (or alternatively, desired) to form a vertical channel transistor are arranged in a relatively narrow and long space due to the down-scaling and higher integration of the semiconductor memory device 100, the semiconductor memory device 100 may provide a structure capable of mitigating or preventing unintended voids or seams from forming during the process of forming the components, for example, the plurality of back gate electrodes BG, which constitute the vertical channel transistor, and mitigating or preventing process defects, such as the thickness nonuniformity of structures (e.g., the plurality of back gate dielectric films 152) having relatively small thicknesses. Therefore, the semiconductor memory device 100 may have a structure effective in making memory cells with finer-sizes and higher degrees of integration and thus exhibit improved reliability.

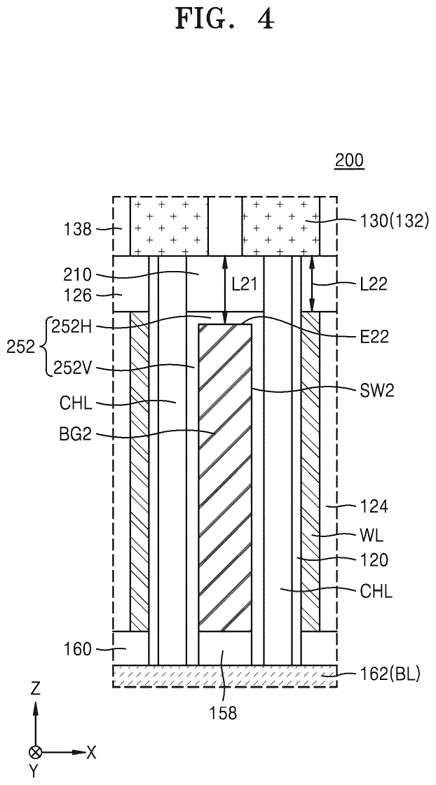

FIG. 4 is a cross-sectional view illustrating a semiconductor memory device 200 according to an example embodiment. FIG. 4 illustrates an enlarged cross-sectional configuration of a portion of the semiconductor memory device 200, which corresponds to the region EX1 of FIG. 2. In FIG. 4, the same reference numerals as in FIGS. 1 to 3 respectively denote the same members, and here, repeated descriptions thereof are omitted.

Referring to FIG. 4, the semiconductor memory device 200 has substantially the same configuration as the semiconductor memory device 100 described with reference to FIGS. 1 to 3. However, the semiconductor memory device 200 may include a back gate electrode BG2, a back gate dielectric film 252, and a first capping insulating pattern 210.

The back gate electrode BG2, the back gate dielectric film 252, and the first capping insulating pattern 210 may respectively have substantially the same configurations as the back gate electrode BG, the back gate dielectric film 152, and the first capping insulating pattern 110, which are described with reference to FIGS. 1 to 3. However, a first vertical distance L21 from the plurality of contact plugs 130 to a second end surface E22 of the back gate electrode BG2 may be equal or similar to a second vertical distance L22 from the plurality of contact plugs 130 to the word line WL. In the vertical direction (Z direction), the length of the first capping insulating pattern 210 may be equal or similar to the length of the first gap-fill insulating pattern 126.

The back gate dielectric film 252 may include a vertical extension portion 252V, which is arranged between the back gate electrode BG2 and the channel region CHL adjacent thereto to cover a sidewall SW2 of the back gate electrode BG2, and a horizontal extension portion 252H covering the second end surface E22 of the back gate electrode BG2, which faces the plurality of contact plugs 130. The vertical extension portion 252V and the horizontal extension portion 252H of the back gate dielectric film 252 may have structures integrally connected to each other. The vertical extension portion 252V of the back gate dielectric film 252 may be in contact with the sidewall SW2 of the back gate electrode BG2 and with the conductive line BL, and the horizontal extension portion 252H of the back gate dielectric film 252 may be in contact with the second end surface E22 of the back gate electrode BG2, which faces the plurality of contact plugs 130.

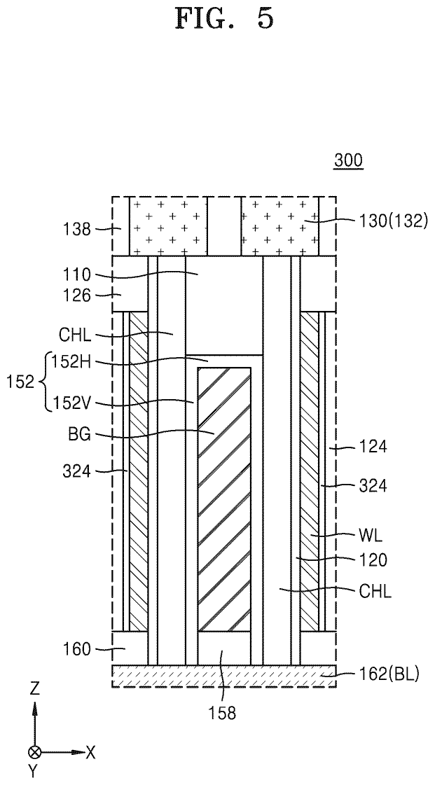

FIG. 5 is a cross-sectional view illustrating a semiconductor memory device 300 according to an example embodiment. FIG. 5 illustrates an enlarged cross-sectional configuration of a portion of the semiconductor memory device 300, which corresponds to the region EX1 of FIG. 2. In FIG. 5, the same reference numerals as in FIGS. 1 to 3 respectively denote the same members, and here, repeated descriptions thereof are omitted.

Referring to FIG. 5, the semiconductor memory device 300 has substantially the same configuration as the semiconductor memory device 100 described with reference to FIGS. 1 to 3. However, the semiconductor memory device 300 may further include a spacer insulating pattern 324 between the word line WL and the isolation insulating pattern 124. In the first horizontal direction (X direction), the width of the spacer insulating pattern 324 may be less than the width of the isolation insulating pattern 124.

In some example embodiments, the spacer insulating pattern 324 and the isolation insulating pattern 124 may include the same material. In some example embodiments, the spacer insulating pattern 324 and the isolation insulating pattern 124 may respectively include different materials. In some example embodiments, each of the spacer insulating pattern 324 and the isolation insulating pattern 124 may include a material selected from silicon nitride (SiN), silicon oxynitride (SiON), silicon carbonitride (SiCN), silicon oxycarbonitride (SiOCN), and silicon boron nitride (SiBN), but the inventive concepts are not limited to the materials set forth above.

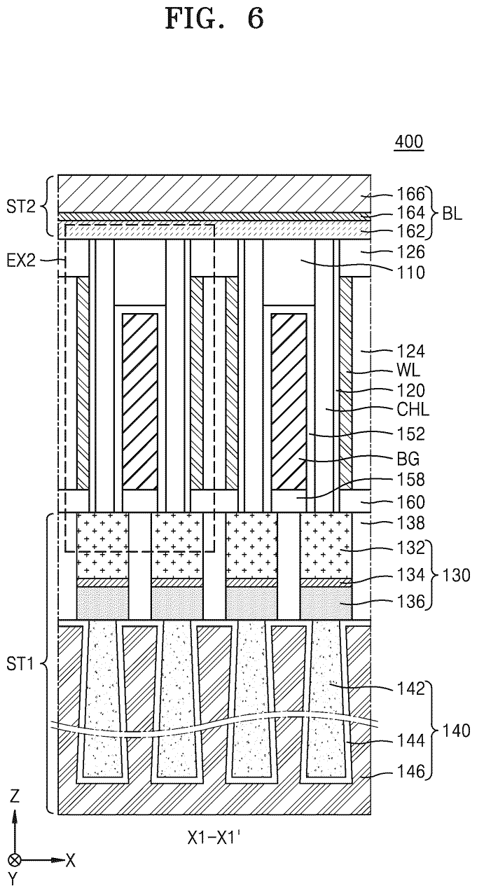

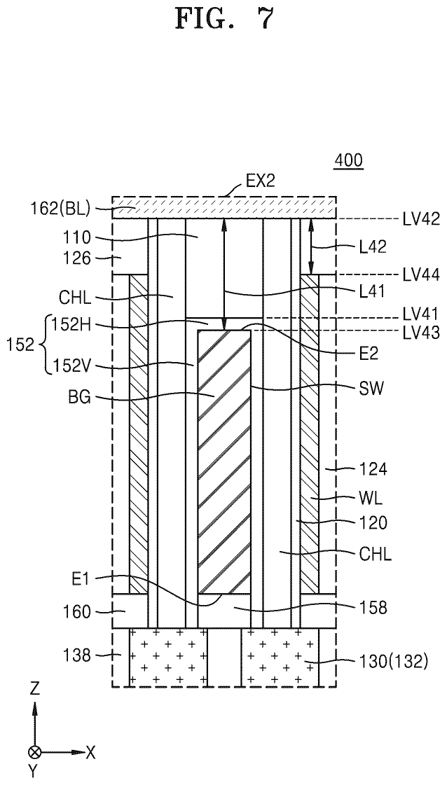

FIG. 6 is a cross-sectional view illustrating a semiconductor memory device 400 according to an example embodiment. FIG. 6 illustrates an enlarged cross-sectional configuration of a portion of the semiconductor memory device 400, which corresponds to the cross-section taken along the line X1-X1′ of FIG. 1. FIG. 7 is an enlarged cross-sectional view of a region EX2 of FIG. 6. In FIGS. 6 and 7, the same reference numerals as in FIGS. 1 to 3 respectively denote the same members, and here, repeated descriptions thereof are omitted.

Referring to FIGS. 6 and 7, the semiconductor memory device 400 has substantially the same configuration as the semiconductor memory device 100 described with reference to FIGS. 1 to 3. However, as compared with the semiconductor memory device 100 described with reference to FIGS. 1 and 3, in the semiconductor memory device 400, the position of a first structure ST1, which includes the plurality of contact plugs 130, the interlayer dielectric 138, and the capacitor structure 140, and the position of a second structure ST2 including the plurality of conductive lines BL are opposite to each other with respect to the plurality of word lines WL, the plurality of back gate electrodes BG, and the plurality of channel regions CHL.

In the semiconductor memory device 400, the back gate electrode BG may have a first end surface E1, which faces the plurality of contact plugs 130, and a second end surface E2, which faces the conductive line BL.

In the semiconductor memory device 400, the back gate dielectric film 152 may be apart from the conductive line BL and may be in contact with one contact plug 130 selected from the plurality of contact plugs 130. The back gate dielectric film 152 may be apart from the conductive line BL in the vertical direction (Z direction) with the first capping insulating pattern 110 therebetween. The back gate dielectric film 152 may include a vertical extension portion 152V, which is arranged between the back gate electrode BG and the channel region CHL adjacent thereto to cover the sidewall SW of the back gate electrode BG, and a horizontal extension portion 152H covering the second end surface E2 of the back gate electrode BG, which faces the conductive line BL. The back gate dielectric film 152 may have a U-like cross-sectional shape, which is open toward the plurality of contact plugs 130, in a cross-sectional view taken in the first horizontal direction (X direction). The vertical extension portion 152V of the back gate dielectric film 152 may be in contact with the sidewall SW of the back gate electrode BG and with the contact plug 130, and the horizontal extension portion 152H of the back gate dielectric film 152 may be in contact with the second end surface E2 of the back gate electrode BG, which faces the conductive line BL.

In a region between a pair of adjacent channel regions CHL, the first capping insulating pattern 110 may be arranged between the horizontal extension portion 152H of the back gate dielectric film 152 and the conductive line BL. In a region between a pair of adjacent channel regions CHL, the second capping insulating pattern 158 may be arranged between the back gate electrode BG and the plurality of contact plugs 130. The horizontal extension portion 152H of the back gate dielectric film 152 may be arranged between the first capping insulating pattern 110 and the back gate electrode BG. The horizontal extension portion 152H of the back gate dielectric film 152 may be apart from the conductive line BL in the vertical direction (Z direction) with the first capping insulating pattern 110 therebetween.

As shown in FIG. 7, a vertical level LV41 of the closest portion of the back gate dielectric film 152 to the conductive line BL in the vertical direction (Z direction) may be closer to the plurality of contact plugs 130 than a vertical level LV42 of the closest portion of the conductive line BL to the back gate electrode BG in the vertical direction (Z direction). A vertical level LV43 of the second end surface E2 of the back gate electrode BG may be farther from the conductive line BL than a vertical level LV44 of the closest end of the word line WL to the conductive line BL. A first vertical distance L41 from the conductive line BL to the second end surface E2 of the back gate electrode BG may be greater than a second vertical distance L42 from the conductive line BL to the word line WL. In the vertical direction (Z direction), the length of the first capping insulating pattern 110 may be greater than the length of the first gap-fill insulating pattern 126.

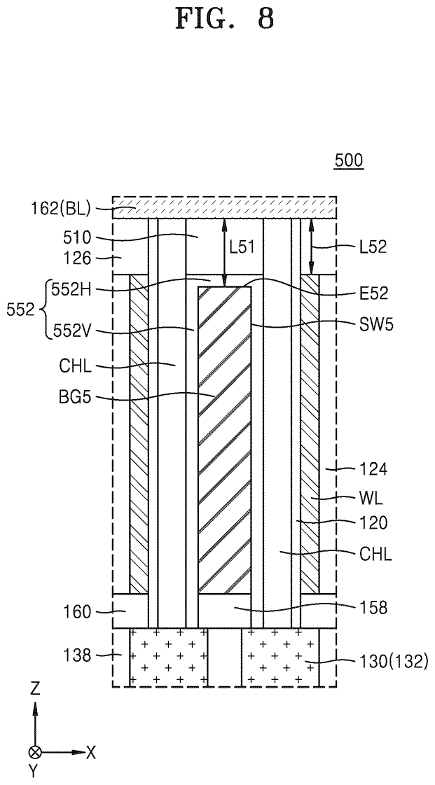

FIG. 8 is a cross-sectional view illustrating a semiconductor memory device 500 according to an example embodiment. FIG. 8 illustrates an enlarged cross-sectional configuration of a portion of the semiconductor memory device 500, which corresponds to the region EX2 of FIG. 6. In FIG. 8, the same reference numerals as in FIGS. 1 to 7 respectively denote the same members, and here, repeated descriptions thereof are omitted.

Referring to FIG. 8, the semiconductor memory device 500 has substantially the same configuration as the semiconductor memory device 400 described with reference to FIGS. 6 and 7. However, the semiconductor memory device 500 may include a back gate electrode BG5, a back gate dielectric film 552, and a first capping insulating pattern 510.

The back gate electrode BG5, the back gate dielectric film 552, and the first capping insulating pattern 510 may respectively have substantially the same configurations as the back gate electrode BG, the back gate dielectric film 152, and the first capping insulating pattern 110, which are described with reference to FIGS. 6 and 7. However, a first vertical distance L51 from the conductive line BL to a second end surface E52 of the back gate electrode BG5 may be equal or similar to a second vertical distance L52 from the conductive line BL to the word line WL. In the vertical direction (Z direction), the length of the first capping insulating pattern 510 may be equal or similar to the length of the first gap-fill insulating pattern 126.

The back gate dielectric film 552 may include a vertical extension portion 552V, which is arranged between the back gate electrode BG5 and the channel region CHL adjacent thereto to cover a sidewall SW5 of the back gate electrode BG5, and a horizontal extension portion 552H covering the second end surface E52 of the back gate electrode BG5, which faces the conductive line BL. The vertical extension portion 552V and the horizontal extension portion 552H of the back gate dielectric film 552 may have structures integrally connected to each other. The vertical extension portion 552V of the back gate dielectric film 552 may be in contact with the sidewall SW5 of the back gate electrode BG5 and with the contact plug 130, and the horizontal extension portion 552H of the back gate dielectric film 552 may be in contact with the second end surface E52 of the back gate electrode BG5, which faces the conductive line BL.

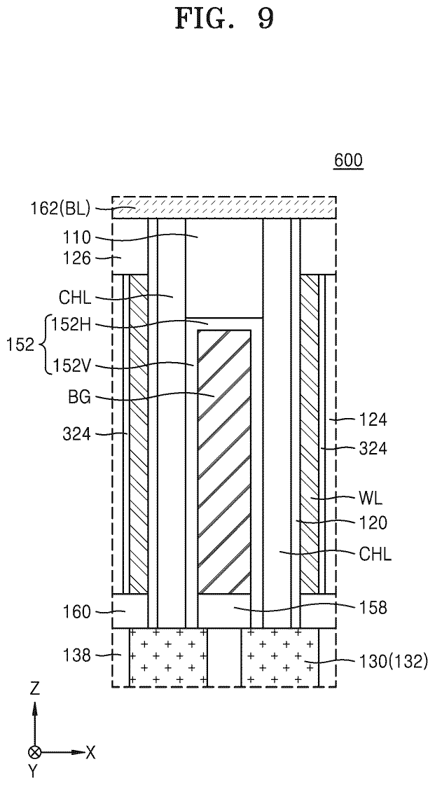

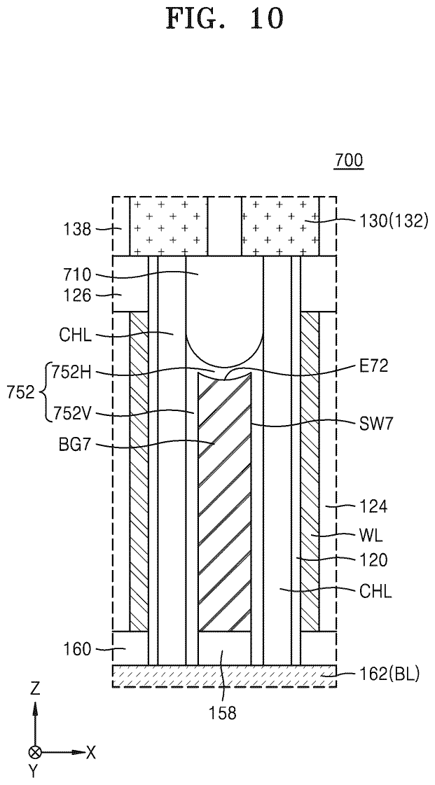

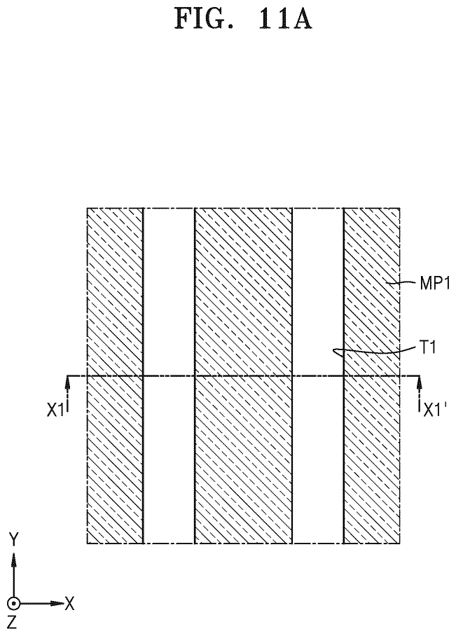

FIG. 9 is a cross-sectional view illustrating a semiconductor memory device 600 according to an example embodiment. FIG. 9 illustrates an enlarged cross-sectional configuration of a portion of the semiconductor memory device 600, which corresponds to the region EX2 of FIG. 6. In FIG. 9, the same reference numerals as in FIGS. 1 to 7 respectively denote the same members, and here, repeated descriptions thereof are omitted.

Referring to FIG. 9, the semiconductor memory device 600 has substantially the same configuration as the semiconductor memory device 400 described with reference to FIGS. 6 and 7. However, the semiconductor memory device 600 may further include a spacer insulating pattern 324 between the word line WL and the isolation insulating pattern 124. In the first horizontal direction (X direction), the width of the spacer insulating pattern 324 may be less than the width of the isolation insulating pattern 124. A more detailed configuration of the spacer insulating pattern 324 is the same as described with reference to FIG. 5.

FIG. 10 is a cross-sectional view illustrating a semiconductor memory device 700 according to an example embodiment. FIG. 10 illustrates an enlarged cross-sectional configuration of a portion of the semiconductor memory device 700, which corresponds to the region EX1 of FIG. 2. In FIG. 10, the same reference numerals as in FIGS. 1 to 3 respectively denote the same members, and here, repeated descriptions thereof are omitted.

Referring to FIG. 10, the semiconductor memory device 700 has substantially the same configuration as the semiconductor memory device 100 described with reference to FIGS. 1 to 3. However, the semiconductor memory device 700 may include a back gate electrode BG7, a back gate dielectric film 752, and a first capping insulating pattern 710.

The back gate electrode BG7, the back gate dielectric film 752, and the first capping insulating pattern 710 may respectively have substantially the same configurations as the back gate electrode BG, the back gate dielectric film 152, and the first capping insulating pattern 110, which are described with reference to FIGS. 1 to 3. The back gate dielectric film 752 may include a vertical extension portion 752V, which is arranged between the back gate electrode BG7 and the channel region CHL adjacent thereto to cover a sidewall SW7 of the back gate electrode BG7, and a horizontal extension portion 752H covering a second end surface E72 of the back gate electrode BG7, which faces the plurality of contact plugs 130. The vertical extension portion 752V and the horizontal extension portion 752H of the back gate dielectric film 752 may have structures integrally connected to each other. The vertical extension portion 752V of the back gate dielectric film 752 may be in contact with the sidewall SW7 of the back gate electrode BG7 and with the conductive line BL, and the horizontal extension portion 752H of the back gate dielectric film 752 may be in contact with the second end surface E72 of the back gate electrode BG7, which faces the plurality of contact plugs 130.

In the semiconductor memory device 700, each of the second end surface E72 of the back gate electrode BG7, which is covered by the horizontal extension portion 752H of the back gate dielectric film 752, and the horizontal extension portion 752H of the back gate dielectric film 752 may have a shape nonlinearly extending in the first horizontal direction (X direction). For example, the second end surface E72 of the back gate electrode BG7 may have a shape that is concave toward the first capping insulating pattern 710, and the horizontal extension portion 752H of the back gate dielectric film 752 may have a shape that is convex toward the back gate electrode BG7 in correspondence with the shape of the second end surface E72 of the back gate electrode BG7. A surface of the first capping insulating pattern 710, which faces the back gate electrode BG7, may have a shape that is convex toward the back gate electrode BG7.

According to the semiconductor memory devices 200, 300, 400, 500, 600, and 700 described with reference to FIGS. 4 to 10, even when components required (or alternatively, desired) to form a vertical channel transistor are arranged in a relatively narrow and long space, each of the semiconductor memory devices 200, 300, 400, 500, 600, and 700 may provide a structure capable of mitigating or preventing unintended voids or seams from forming during the process of forming the components, for example, the plurality of back gate electrodes BG, BG2, BG5, and BG7, which each constitute the vertical channel transistor, and mitigating or preventing process defects, such as the thickness nonuniformity of structures (e.g., the plurality of back gate dielectric films 152, 252, 552, and 752) having relatively small thicknesses. Therefore, each of the semiconductor memory devices 200, 300, 400, 500, 600, and 700 may have a structure effective in making memory cells with finer-sizes and higher degrees of integration and thus exhibit improved reliability.

Next, methods of fabricating a semiconductor memory device, according to some example embodiments, are described by taking specific examples.

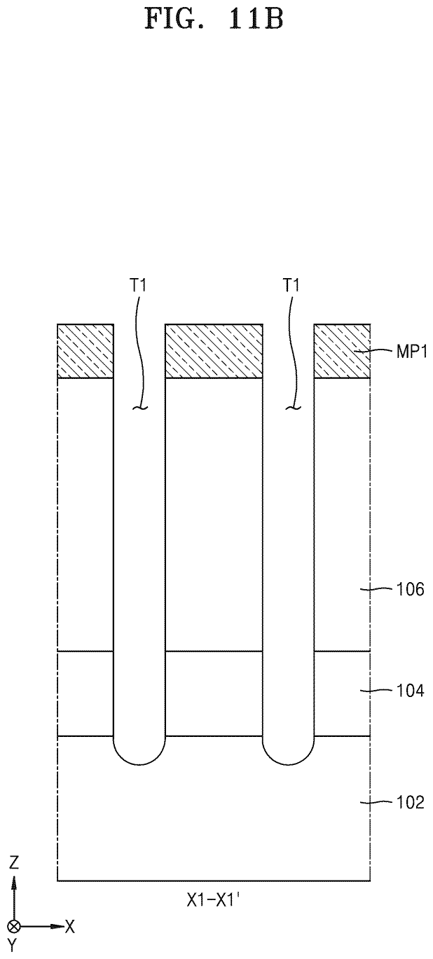

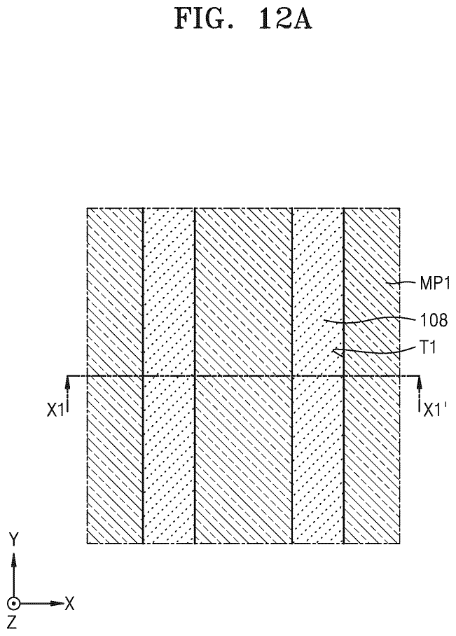

FIGS. 11A to 30 are diagrams respectively illustrating a sequence of processes of a method of fabricating a semiconductor memory device, according to an example embodiments. More specifically, FIGS. 11A, 12A, 13A, 14A, 15A, 16A, 17A, 19A, 22A, 23A, and 27A are planar layout diagrams each illustrating some components of the semiconductor memory device, according to the sequence of processes, to describe the method of fabricating the semiconductor memory device. FIGS. 11B, 12B, 13B, 14B, 15B, 16B, 17B, 18, 19B, 20, 21, 22B, 23B, 24, 25, 26, 27B, 28, 29, and 30 are cross-sectional views each illustrating a portion of the semiconductor memory device, which corresponds to the cross-section taken along the line X1-X1′ in FIG. 1, according to the sequence of processes, and FIGS. 11B, 12B, 13B, 14B, 15B, 16B, 17B, 19B, 22B, 23B, and 27B are cross-sectional views of the semiconductor memory device, taken along the lines X1-X1′ of FIGS. 11A, 12A, 13A, 14A, 15A, 16A, 17A, 19A, 22A, 23A, and 27A, respectively. An example of a method of fabricating the semiconductor memory device 100 shown in FIGS. 1 to 3 is described with reference to FIGS. 11A to 30. In FIGS. 11A to 30, the same reference numerals as in FIGS. 1 to 3 respectively denote the same members, and here, repeated descriptions thereof are omitted.

Referring to FIGS. 11A and 11B, a substrate structure including a substrate 102, a gap-fill insulating layer 104, and an active layer 106 may be prepared.

The substrate structure may include a silicon-on-insulator (SOI) substrate. The substrate 102 may include a silicon substrate. The gap-fill insulating layer 104 may include a silicon oxide film. The active layer 106 may include at least one selected from Ge, SiGe, SiC, GaAs, InAs, and InP. In some example embodiments, the active layer 106 may include an impurity-doped well or an impurity-doped structure.

A mask pattern MP1 may be formed on the active layer 106 of the substrate structure. The mask pattern MP1 may include a silicon nitride film. In some example embodiments, an oxide film may be arranged between the active layer 106 and the mask pattern MP1.

Portions of the substrate structure may be etched by using the mask pattern MP1 as an etch mask, thereby forming a plurality of first trenches T1. The plurality of first trenches T1 may be formed to pass through the active layer 106 and the gap-fill insulating layer 104 in the vertical direction (Z direction) and to extend lengthwise in the second horizontal direction (Y direction).

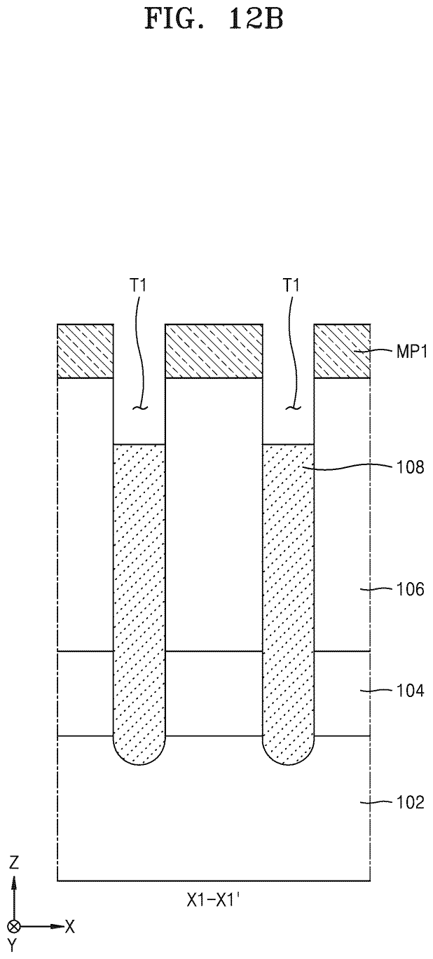

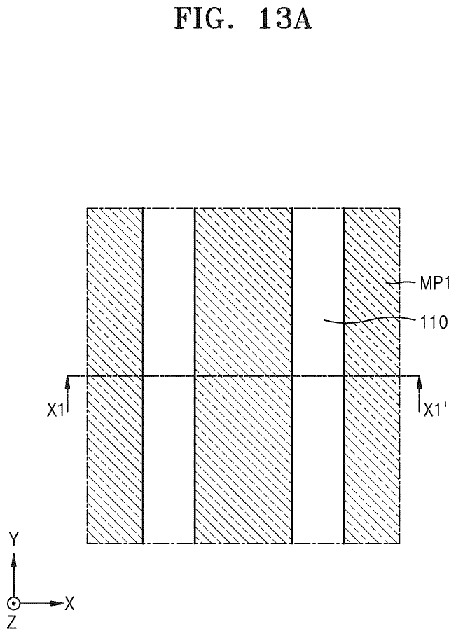

Referring to FIGS. 12A and 12B, in the resulting product of FIGS. 11A and 11B, a plurality of sacrificial films 108 may be formed to fill portions of the plurality of first trenches T1, respectively.

Each of the plurality of sacrificial films 108 may include a material having etch selectivity with respect to a constituent material of each of the active layer 106 and the mask pattern MP1. In some example embodiments, each of the plurality of sacrificial films 108 may include, but is not limited to, metal, a metal nitride, or a combination thereof.

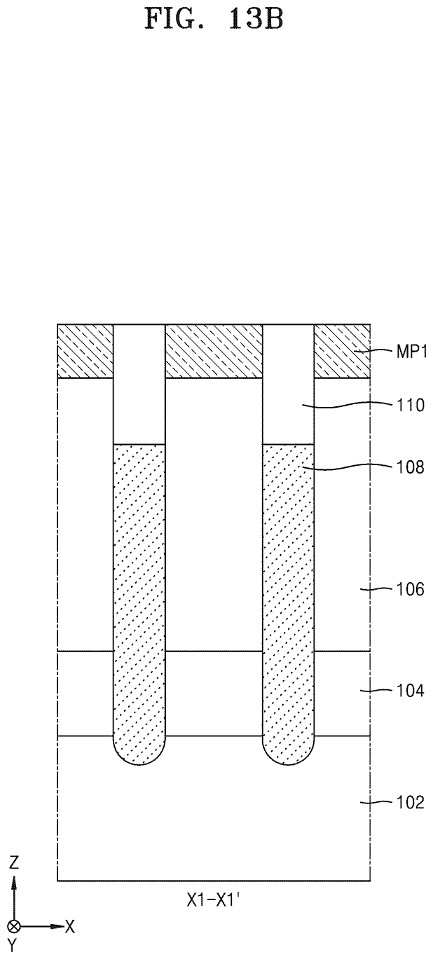

Referring to FIGS. 13A and 13B, in the resulting product of FIGS. 12A and 12B, a plurality of first capping insulating patterns 110 may be formed to fill the remaining portions of the plurality of first trenches T1 over the plurality of sacrificial films 108, respectively.

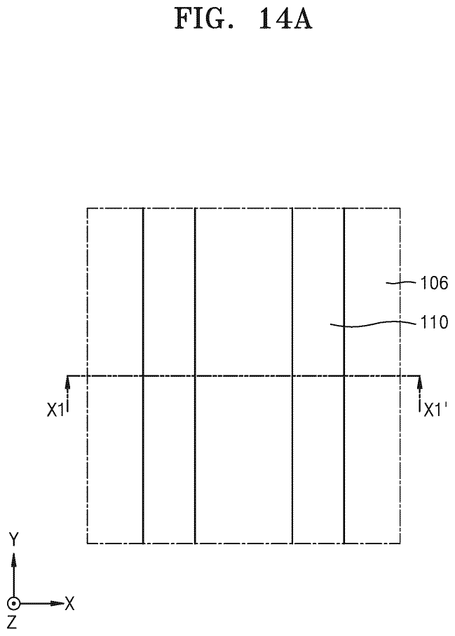

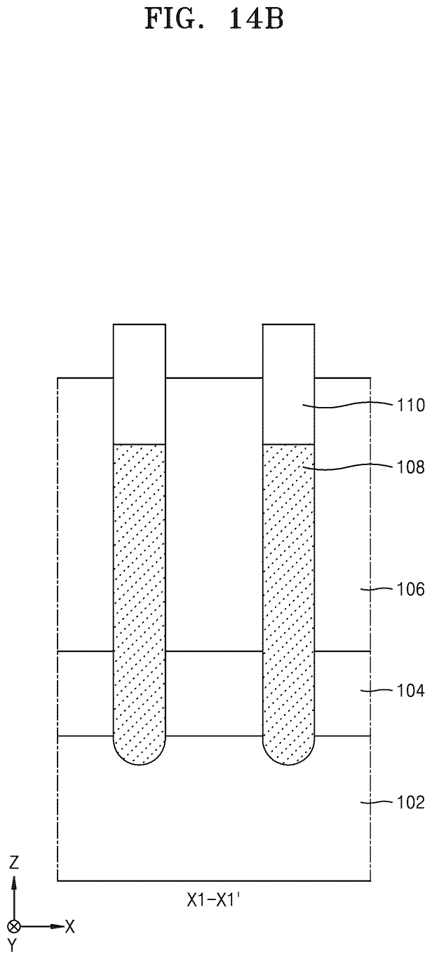

Referring to FIGS. 14A and 14B, the mask pattern MP1 may be removed from the resulting product of FIGS. 13A and 13B, thereby exposing the active layer 106 around the plurality of first capping insulating patterns 110.

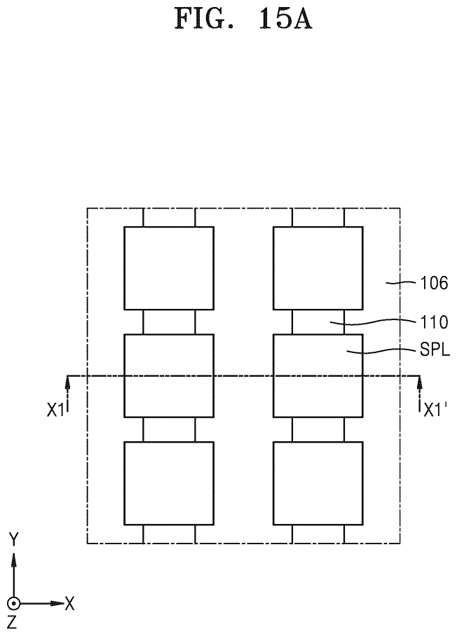

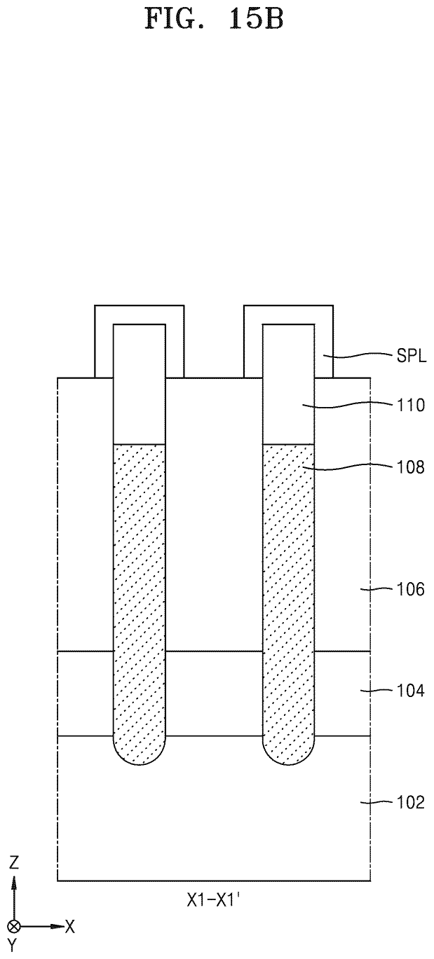

Referring to FIGS. 15A and 15B, a plurality of spacer layers SPL may each be formed to cover a portion of each of the plurality of first capping insulating patterns 110 and a portion of the active layer 106 around each of the plurality of first capping insulating patterns 110. Each of the plurality of spacer layers SPL may include a silicon oxide film. The plurality of spacer layers SPL may include a first group of spacer layers SPL, which are arranged in a line in the first horizontal direction (X direction) and apart from each other in the first horizontal direction (X direction), and a second group of spacer layers SPL, which are arranged in a line in the second horizontal direction (Y direction) and apart from each other in the second horizontal direction (Y direction).

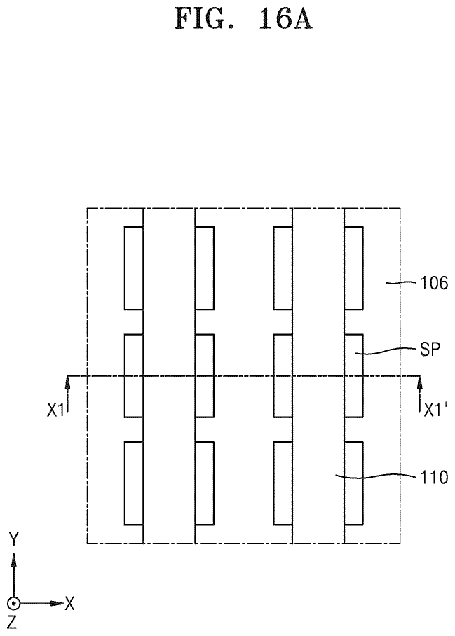

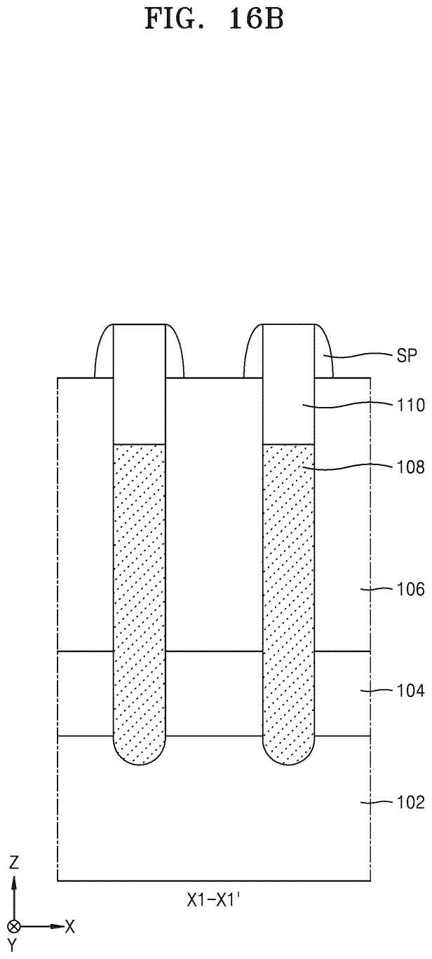

Referring to FIGS. 16A and 16B, the plurality of spacer layers SPL may be etched-back, thereby forming a plurality of spacers SP, which respectively cover both sidewalls of each of the plurality of first capping insulating patterns 110 in terms of the first horizontal direction (X direction). Portions of the upper surface of the active layer 106, which are adjacent to each of the plurality of first capping insulating patterns 110, may be covered by the plurality of spacers SP, respectively.

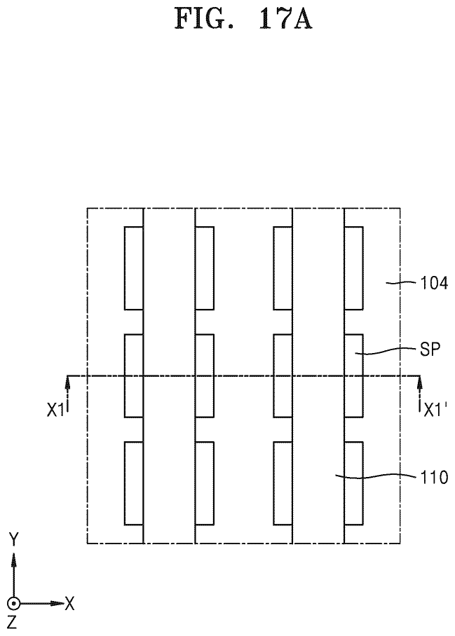

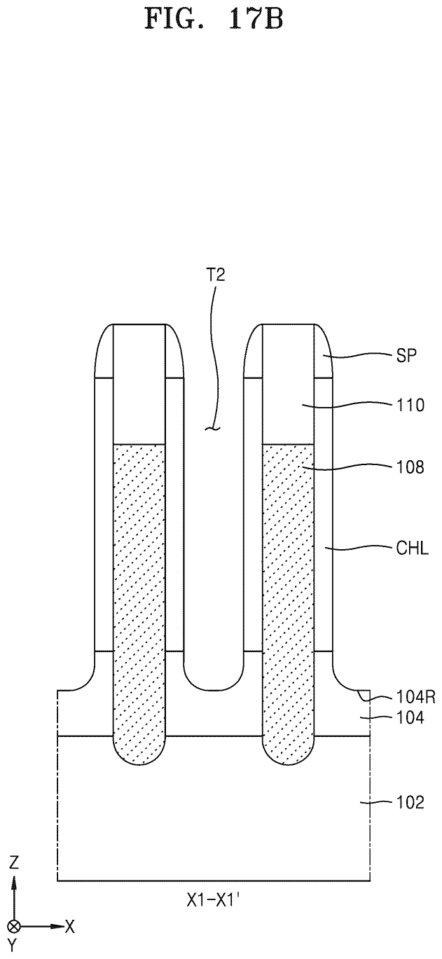

Referring to FIGS. 17A and 17B, the active layer 106 may be etched by using the plurality of first capping insulating patterns 110 and the plurality of spacers SP as an etch mask, thereby forming a plurality of second trenches T2. Thus, portions of the active layer 106, which are respectively located under the plurality of spacers SP, may remain as a plurality of channel regions CHL, respectively. The gap-fill insulating layer 104 may be partially etched due to over-etching during the process of etching the active layer 106, and thus, a plurality of recess regions 104R may be formed in the upper surface of the gap-fill insulating layer 104 and defines bottom boundaries of the plurality of second trenches T2, respectively.

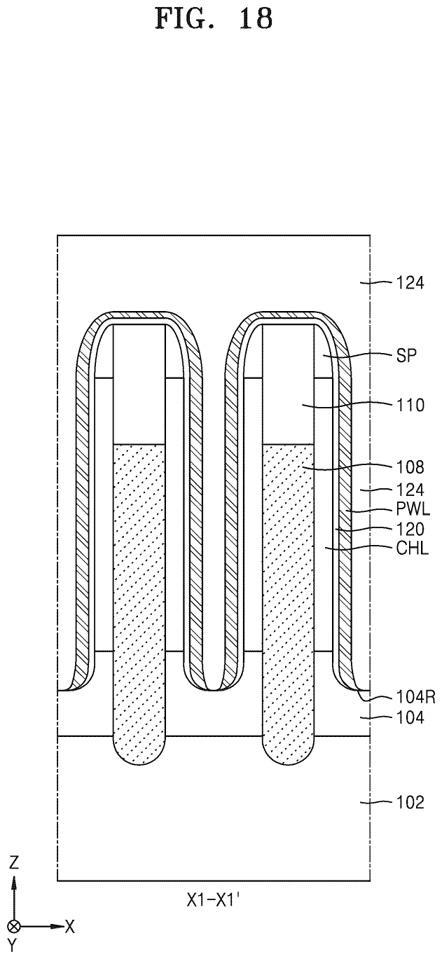

Referring to FIG. 18, a gate dielectric film 120 may be formed to conformally cover the resulting product of FIGS. 17A and 17B, followed by forming a conductive layer to conformally cover the gate dielectric film 120, and then, a portion of the conductive layer in each recess region 104R of the gap-fill insulating layer 104 may be etched, thereby dividing the conductive layer into a plurality of preliminary word lines PWL. Next, an isolation insulating pattern 124 may be formed to fill a space above each of the plurality of preliminary word lines PWL. The isolation insulating pattern 124 may be formed to fill each space between the plurality of preliminary word lines PWL and to cover the upper surface of each of the plurality of preliminary word lines PWL. A constituent material of the conductive layer is the same as the constituent material of the word line WL described above.

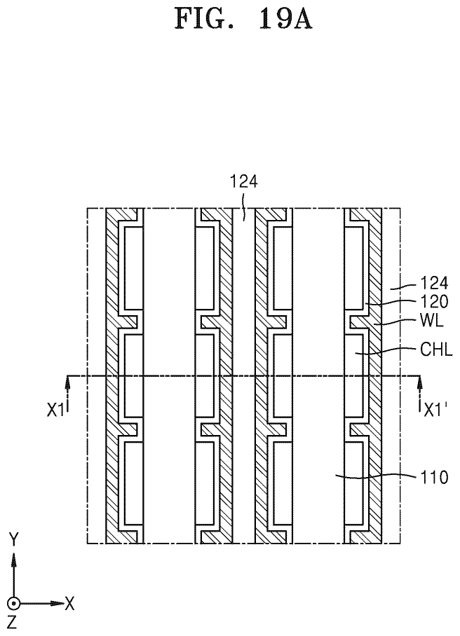

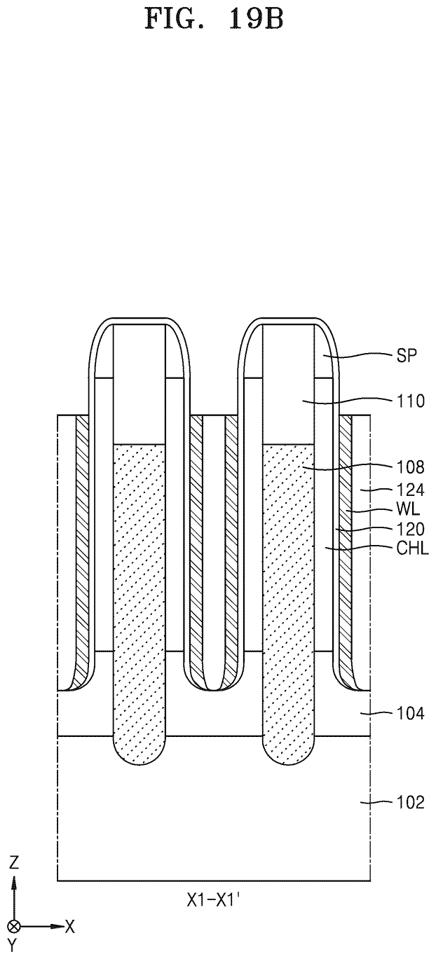

Referring to FIGS. 19A and 19B, in the resulting product of FIG. 18, each of the plurality of preliminary word lines PWL may be partially exposed by etching-back the isolation insulating pattern 124 such that an upper portion of the isolation insulating pattern 124 is removed, and each of the plurality of preliminary word lines PWL that are exposed may be etched, thereby forming a plurality of word lines WL.

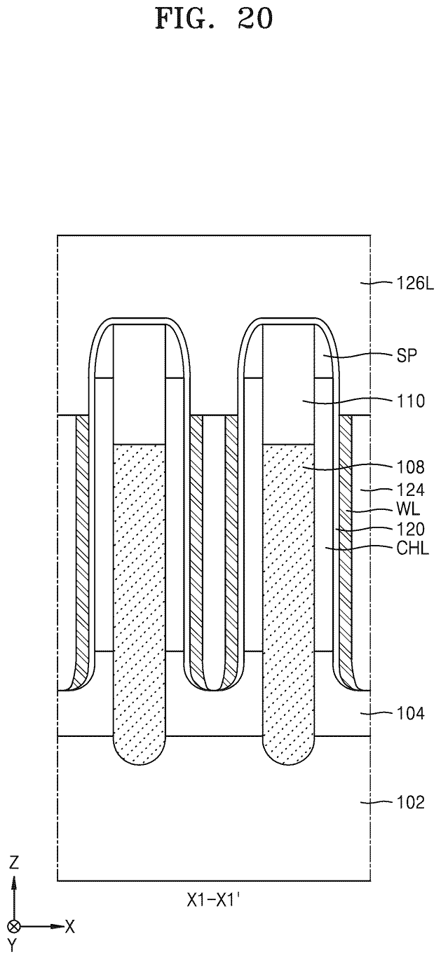

Referring to FIG. 20, a first gap-fill insulating film 126L may be formed to cover the resulting product of FIGS. 19A and 19B. A constituent material of the first gap-fill insulating film 126L is the same as the constituent material of the first gap-fill insulating pattern 126 described above.

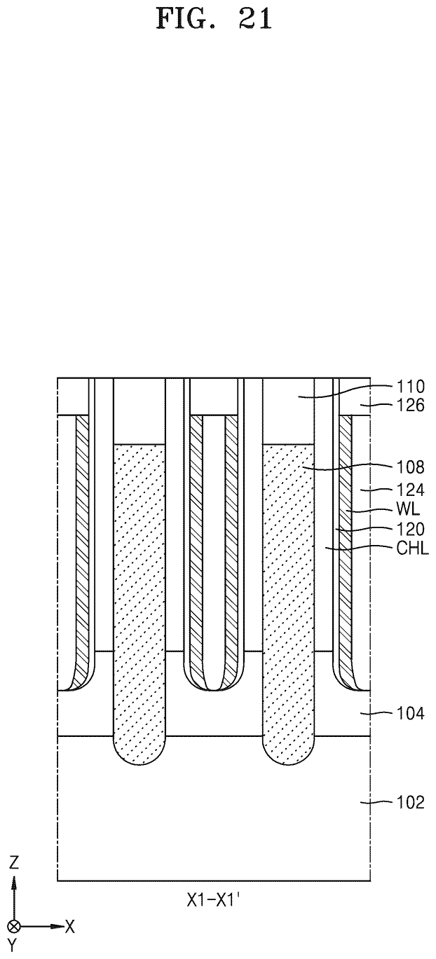

Referring to FIG. 21, a planarization process may be performed on the resulting product of FIG. 20 from the exposed upper surface of the first gap-fill insulating film 126L, thereby exposing the plurality of channel regions CHL and forming the first gap-fill insulating pattern 126 from the first gap-fill insulating film 126L. After the plurality of channel regions CHL are exposed, the height of the uppermost portion of each of the first capping insulating pattern 110 and the gate dielectric film 120 in the resulting product of FIG. 20 may be reduced.

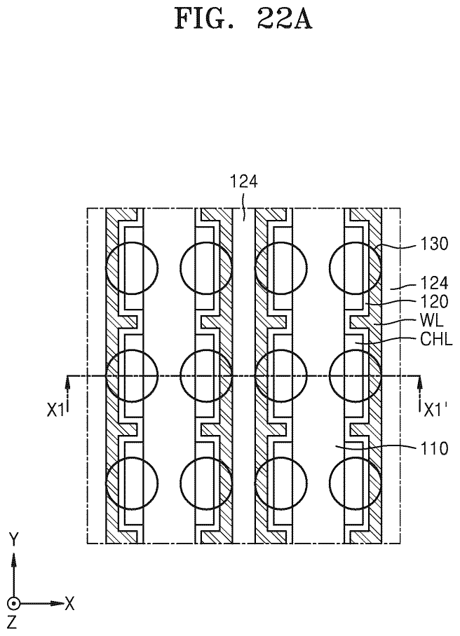

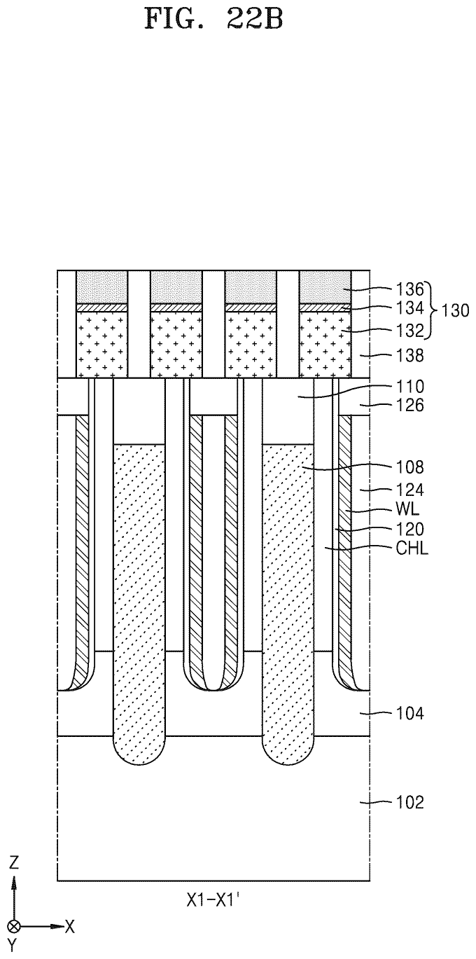

Referring to FIGS. 22A and 22B, in the resulting product of FIG. 21, a plurality of contact plugs 130 may be respectively formed on the plurality of channel regions CHL, and an interlayer dielectric 138 may be formed to fill each space between the plurality of contact plugs 130.

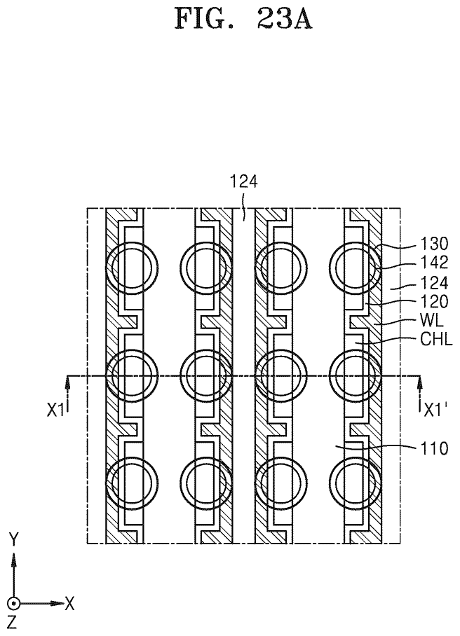

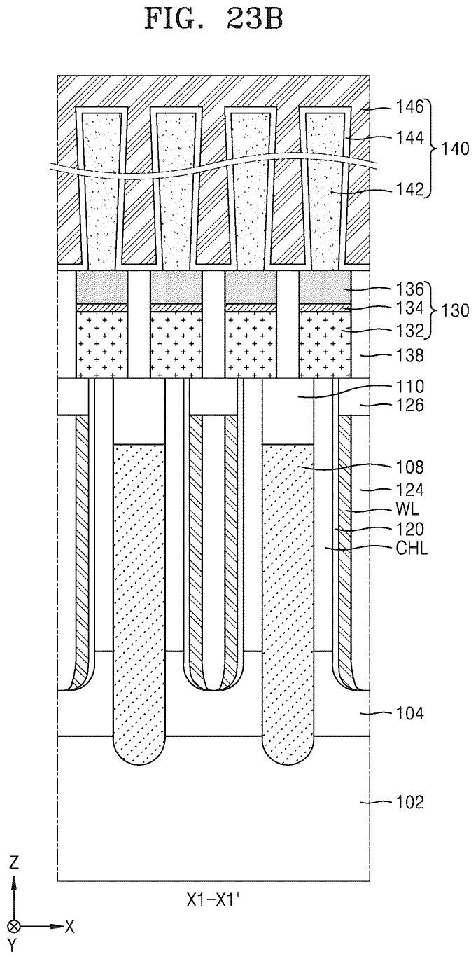

Referring to FIGS. 23A and 23B, a capacitor structure 140 may be formed on the resulting product of FIGS. 22A and 22B to be connected to the plurality of contact plugs 130.

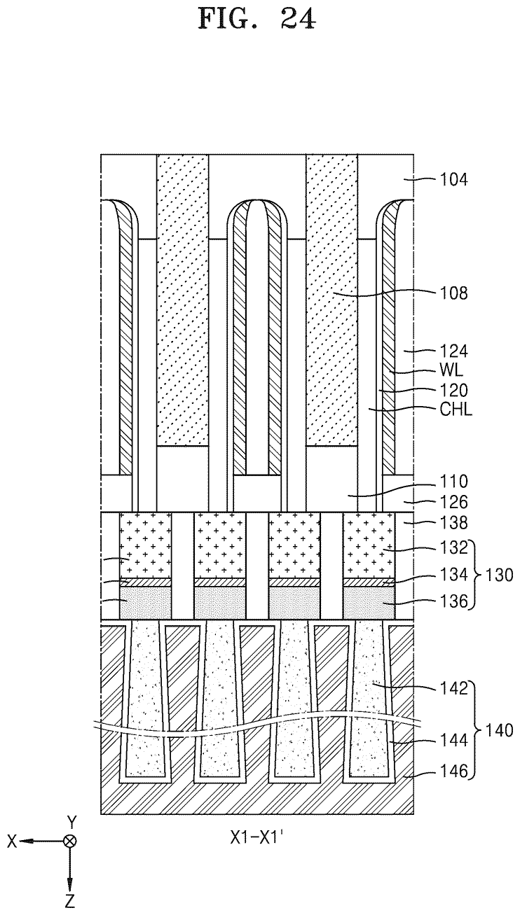

Referring to FIG. 24, the substrate 102 may face upwards in the vertical direction (Z direction) by turning the resulting product of FIGS. 23A and 23B upside-down such that the directions, in which upper and lower portions of the resulting product of FIGS. 23A and 23B in terms of the vertical direction (Z direction) respectively face, are changed opposite to each other, and a grinding process and a wet etching process may be sequentially performed in the stated order on the substrate 102 from the backside surface of the substrate 102, which is exposed, such that the gap-fill insulating layer 104 and a sacrificial film 108 are exposed.

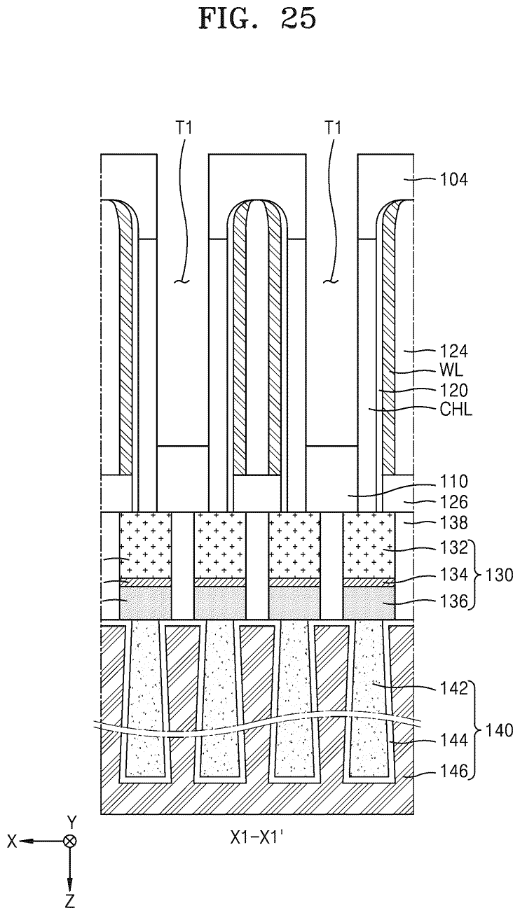

Referring to FIG. 25, the plurality of sacrificial films 108 may be removed from the resulting product of FIG. 24, thereby exposing the first capping insulating pattern 110 by each of the plurality of first trenches T1.

Referring to FIG. 26, in the resulting product of FIG. 25, a back gate dielectric film 152 may be formed to conformally cover respective surfaces of the plurality of channel regions CHL and the plurality of first capping insulating patterns 110, which are exposed by the plurality of first trenches T1, and a conductive layer 154 may be formed on the back gate dielectric film 152 to fill the respective remaining spaces of the plurality of first trenches T1.

A constituent material of the conductive layer 154 is the same as the constituent material of the back gate electrode BG described above.

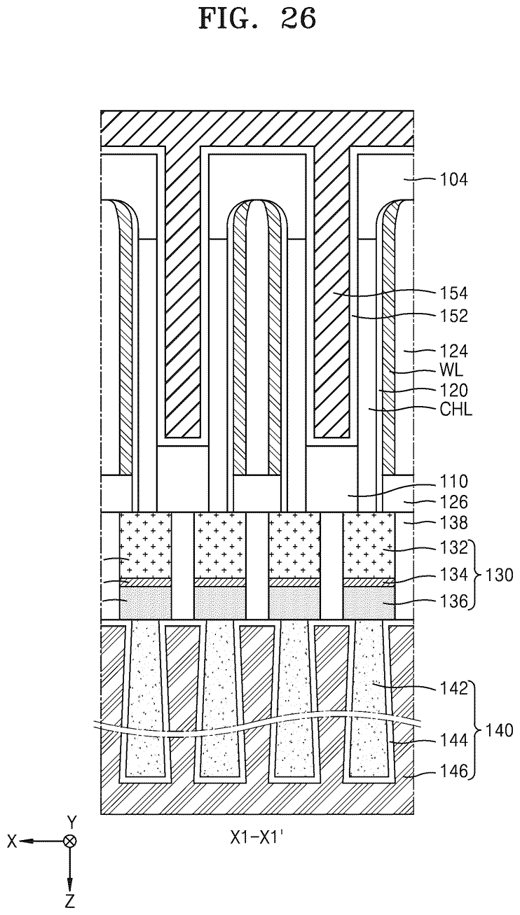

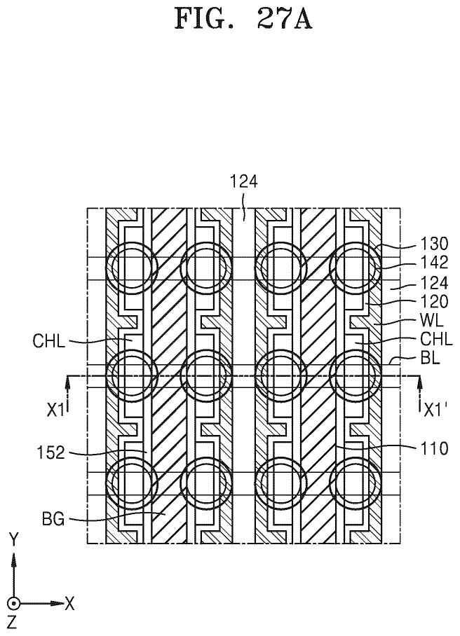

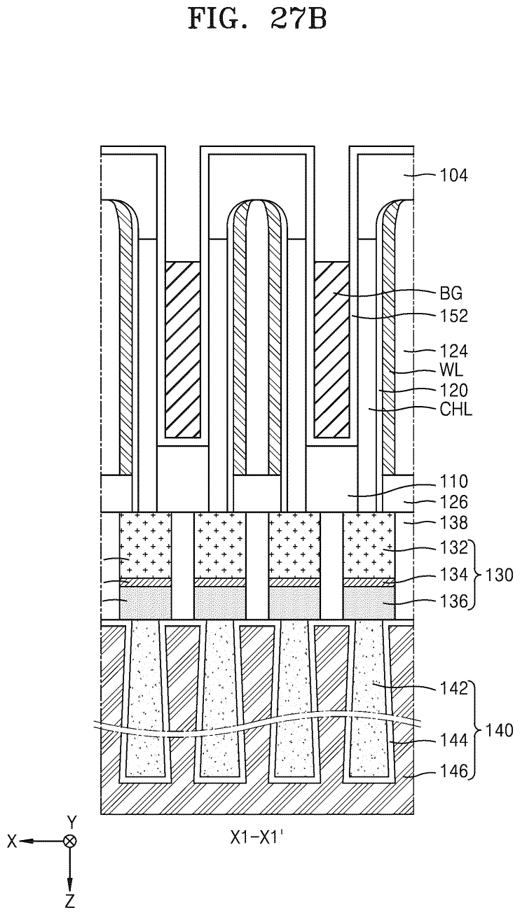

Referring to FIGS. 27A and 27B, in the resulting product of FIG. 26, a portion of the conductive layer 154 may be etched-back, thereby forming a plurality of back gate electrodes BG from the conductive layer 154.

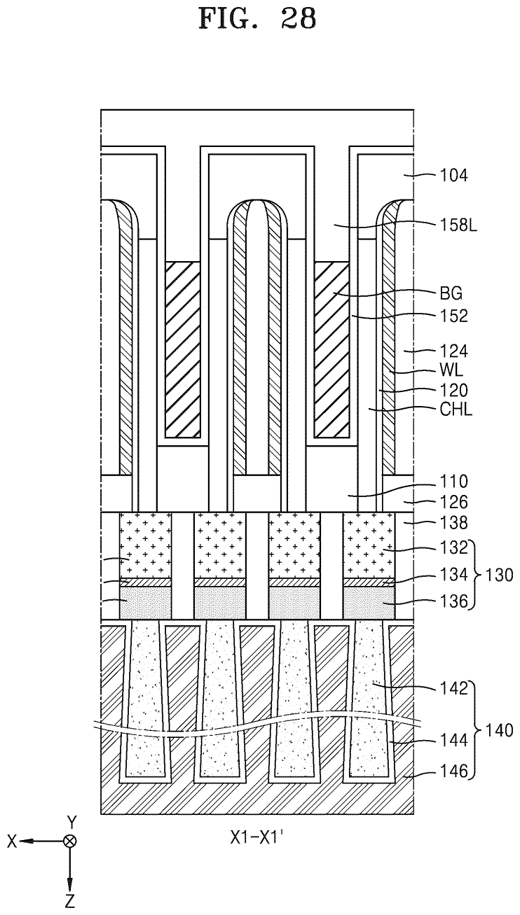

Referring to FIG. 28, a second capping insulating layer 158L may be formed to cover the plurality of back gate electrodes BG. A constituent material of the second capping insulating layer 158L is the same as the constituent material of the second capping insulating pattern 158 described above.

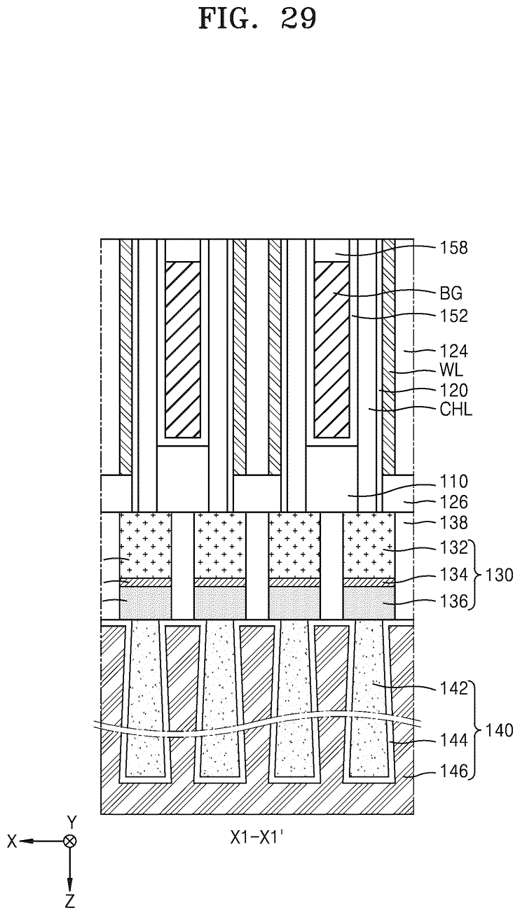

Referring to FIG. 29, a planarization process may be performed on the resulting product of FIG. 28 from the exposed surface of the second capping insulating layer 158L, thereby exposing the plurality of channel regions CHL. Thus, the second capping insulating layer 158L may be divided into a plurality of second capping insulating patterns 158, and the respective exposed surfaces of the plurality of second capping insulating patterns 158, the plurality of word lines WL, and a plurality of isolation insulating patterns 124 may be coplanar with the exposed surfaces of the plurality of channel regions CHL.

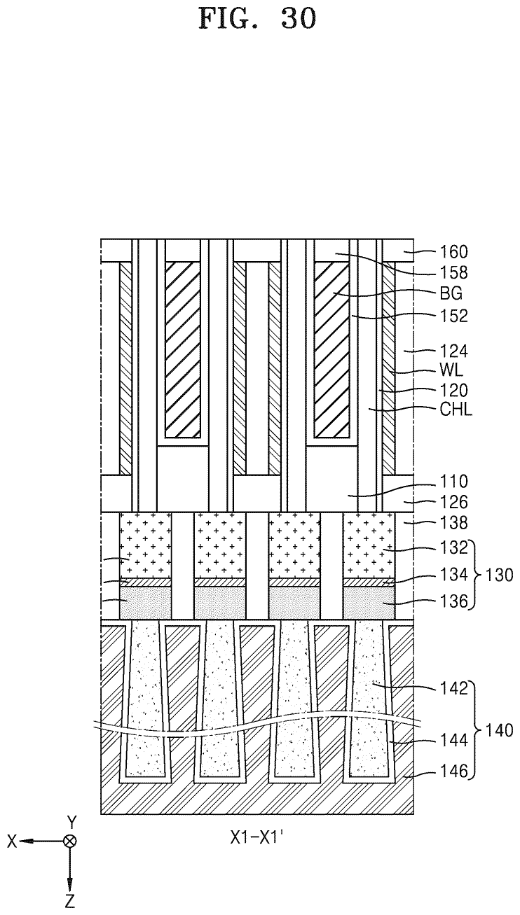

Referring to FIG. 30, in the resulting product of FIG. 29, a space may be prepared above each of the plurality of word lines WL and the plurality of isolation insulating patterns 124 by removing a portion of each of the plurality of word lines WL and the plurality of isolation insulating patterns 124 from the exposed surface of each thereof, and then, a second gap-fill insulating pattern 160 may be formed to fill the space.

Next, as shown in FIG. 2, the plurality of conductive lines BL may be formed on the resulting product of FIG. 30, thereby fabricating the semiconductor memory device 100 shown in FIG. 3.

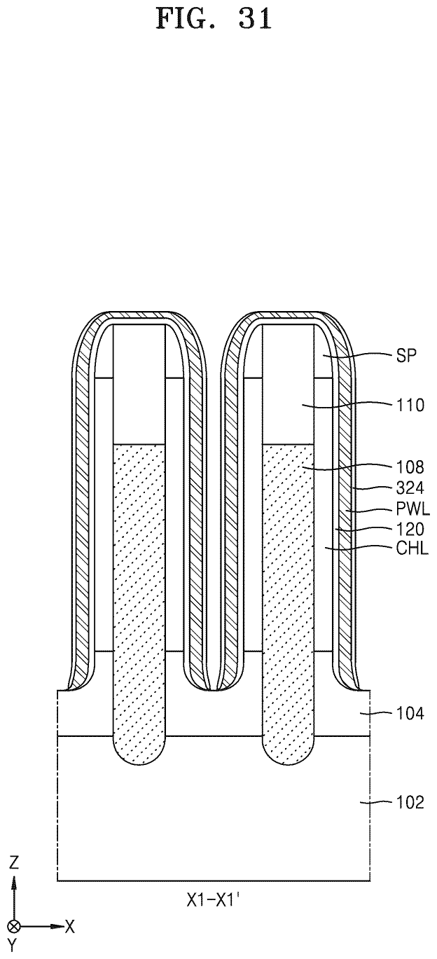

FIG. 31 is a cross-sectional view illustrating a method of fabricating a semiconductor memory device, according to an example embodiment. FIG. 31 illustrates a cross-sectional configuration of a portion of the semiconductor memory device, which corresponds to the cross-section taken along the line X1-X1′ in FIG. 1. An example of a method of fabricating the semiconductor memory device 300 shown in FIG. 5 is described with reference to FIG. 31. In FIG. 31, the same reference numerals as in FIGS. 1 to 30 respectively denote the same members, and here, repeated descriptions thereof are omitted.

Referring to FIG. 31, the processes described with reference to FIGS. 11A to 18 may be performed. However, after a conductive layer is formed to conformally cover the gate dielectric film 120 according to the process described with reference to FIG. 18, and before a portion of the conductive layer in the recess region 104R of the gap-fill insulating layer 104 is etched, the spacer insulating pattern 324 may be formed to cover a sidewall of the conductive layer, as shown in FIG. 31, and the conductive layer may be etched by using the spacer insulating pattern 324 as an etch mask, thereby dividing the conductive layer into the plurality of preliminary word lines PWL.

Next, while the spacer insulating pattern 324 is left on the sidewall of each of the plurality of preliminary word lines PWL, the processes described with reference to FIGS. 19A to 30 may be performed, thereby fabricating the semiconductor memory device 300 shown in FIG. 5.

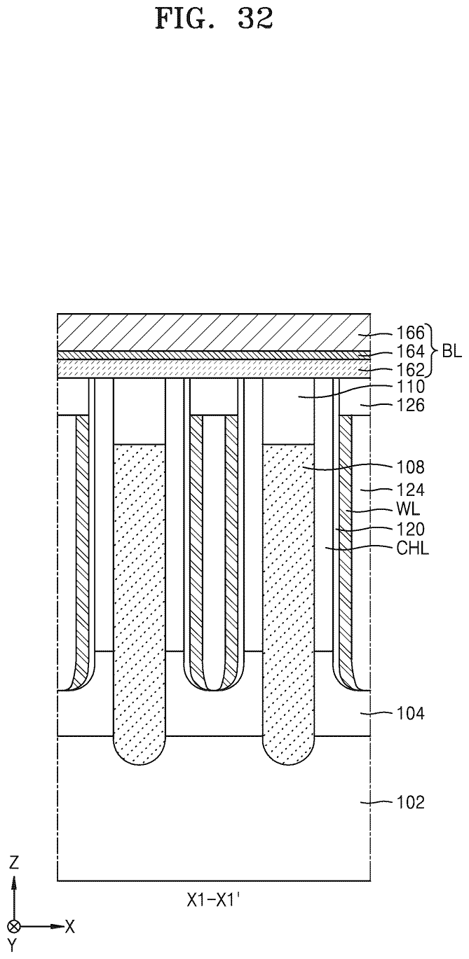

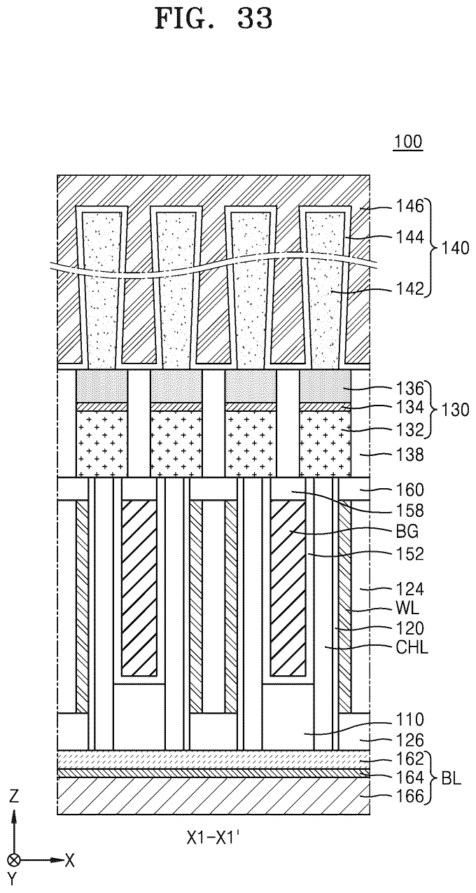

FIGS. 32 and 33 are cross-sectional views illustrating a method of fabricating a semiconductor memory device, according to an example embodiment. FIGS. 32 and 33 each illustrate a cross-sectional configuration of a portion of the semiconductor memory device, which corresponds to the cross-section taken along the line X1-X1′ in FIG. 1. An example of a method of fabricating the semiconductor memory device 400 shown in FIGS. 6 and 7 is described with reference to FIGS. 32 and 33. In FIGS. 32 and 33, the same reference numerals as in FIGS. 1 to 30 respectively denote the same members, and here, repeated descriptions thereof are omitted.

Referring to FIG. 32, the processes described with reference to FIGS. 11A to 21 may be performed. Next, as shown in FIG. 32, in the resulting product of FIG. 21, the conductive line BL may be formed on the plurality of channel regions CHL.

Referring to FIG. 33, in the resulting product of FIG. 32, the processes described with reference to FIGS. 24 to 30 may be performed on a backside surface of the substrate 102. Next, as shown in FIG. 33, the plurality of contact plugs 130 may be formed, followed by forming the interlayer dielectric 138 to fill each space between the plurality of contact plugs 130, and then, the capacitor structure 140 may be formed on the plurality of contact plugs 130 and the interlayer dielectric 138, thereby forming the semiconductor memory device 400 shown in FIGS. 6 and 7.

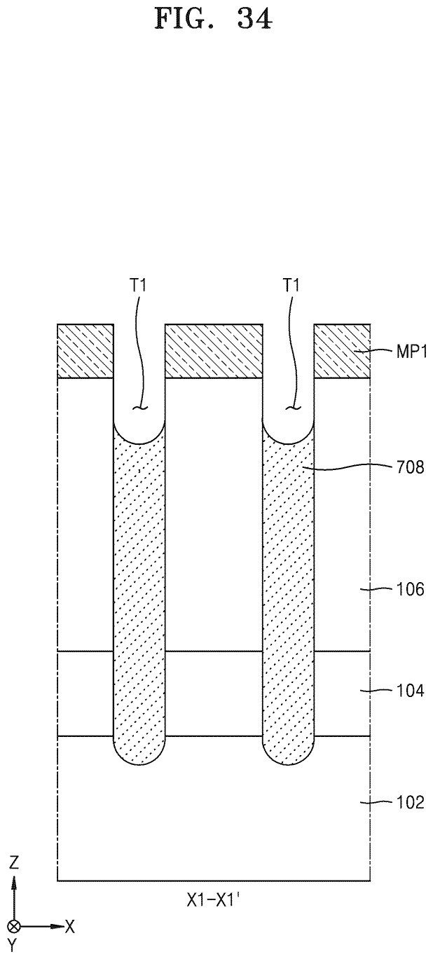

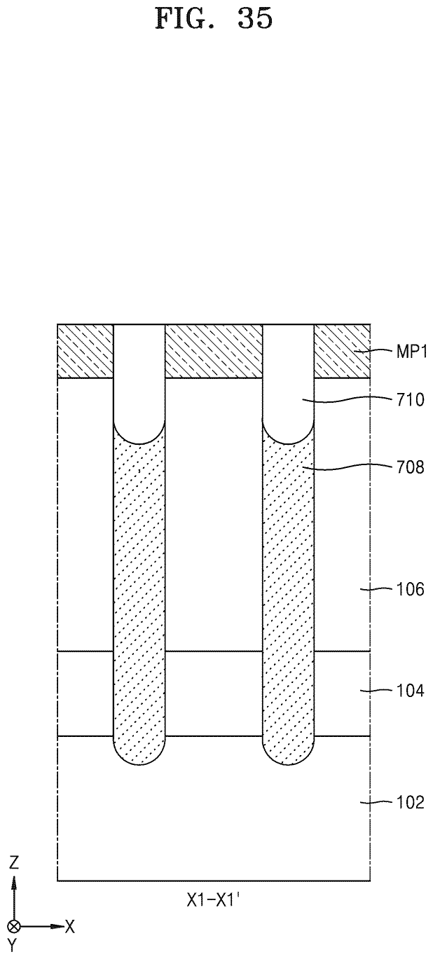

FIGS. 34 and 35 are cross-sectional views illustrating a method of fabricating a semiconductor memory device, according to an example embodiment. FIGS. 34 and 35 each illustrate a cross-sectional configuration of a portion of the semiconductor memory device, which corresponds to the cross-section taken along the line X1-X1′ in FIG. 1. An example of a method of fabricating the semiconductor memory device 700 shown in FIG. 10 is described with reference to FIGS. 34 and 35. In FIGS. 34 and 35, the same reference numerals as in FIGS. 1 to 30 respectively denote the same members, and here, repeated descriptions thereof are omitted.

Referring to FIG. 34, the processes described with reference to FIGS. 11A to 12B may be performed. However, in the process described with reference to FIGS. 12A and 12B, a plurality of sacrificial films 708 may be formed instead of the plurality of sacrificial films 108. Each of the plurality of sacrificial films 708 may have an upper surface that is concave toward an upper space of the first trench T1. To form the plurality of sacrificial films 708, in the resulting product of FIGS. 11A and 11B, a preliminary sacrificial film may be formed to fill the plurality of first trenches T1, followed by removing a portion of the preliminary sacrificial film by etch-back, thereby leaving the plurality of sacrificial films 708 in the plurality of first trenches, respectively. By controlling a process atmosphere when an etch-back process is performed on the portion of the preliminary sacrificial film, the upper surface of each of the plurality of sacrificial films 708 may have a shape that is concave toward the upper space of the first trench T1.

Referring to FIG. 35, in the resulting product of FIG. 34, a plurality of first capping insulating patterns 710 may be formed to fill the remaining portions of the plurality of first trenches T1 above the plurality of sacrificial films 708, respectively.

Next, the processes described with reference to FIGS. 14A to 30 may be performed, thereby fabricating the semiconductor memory device 700 shown in FIG. 10.

Heretofore, although the examples of the methods of fabricating the semiconductor memory devices 100, 300, 400, and 700 shown in FIGS. 1 to 3, 5 to 7, and 10 have been described with reference to FIGS. 11A to 35, it will be understood by those of ordinary skill in the art that semiconductor memory devices having various structures modified and changed from the semiconductor memory devices 100, 300, 400, and 700 shown in FIGS. 1 to 3, 5 to 7, and 10 may be fabricated by making various modifications and changes to the examples described with reference to FIGS. 11A to 35 without departing from the spirit and scope of the inventive concepts.

While the inventive concepts have been particularly shown and described with reference to some example embodiments thereof, it will be understood that various changes in form and details may be made therein without departing from the spirit and scope of the following claims.

What is claimed is:

1. A semiconductor memory device comprising:
a conductive line extending lengthwise in a first horizontal direction;
first and second channel regions over the conductive line and apart from each other in the first horizontal direction, each of the first and second channel regions configured to be connected to the conductive line;
a plurality of contact plugs apart from the conductive line in a vertical direction with the first and second channel regions therebetween, the plurality of contact plugs aligned in the first horizontal direction;
a back gate electrode extending lengthwise in a second horizontal direction between the first and second channel regions, the back gate electrode being apart from the conductive line and each of the plurality of contact plugs in the vertical direction, the second horizontal direction being perpendicular to the first horizontal direction; and
a back gate dielectric film covering surfaces of the back gate electrode,
wherein the back gate dielectric film comprises a vertical extension portion and a horizontal extension portion, the vertical extension portion being between the back gate electrode and the first channel region and between the back gate electrode and the second channel region and covering sidewalls of the back gate electrode, the horizontal extension portion integrally connected to the vertical extension portion and covering an end surface of the back gate electrode at one position selected from a first position facing the conductive line and a second position facing the plurality of contact plugs.

2. The semiconductor memory device of claim 1, wherein the back gate electrode has a first end surface facing the conductive line and a second end surface facing the plurality of contact plugs, and
the horizontal extension portion of the back gate dielectric film is apart from the plurality of contact plugs in the vertical direction and is in contact with the second end surface of the back gate electrode.

3. The semiconductor memory device of claim 1, wherein the back gate electrode has a first end surface facing the plurality of contact plugs and a second end surface facing the conductive line, and
the horizontal extension portion of the back gate dielectric film is apart from the conductive line in the vertical direction and is in contact with the second end surface of the back gate electrode.

4. The semiconductor memory device of claim 1, further comprising:
a first capping insulating pattern being between the first channel region and the second channel region, overlapping the back gate electrode in the vertical direction, and located between the back gate electrode and the plurality of contact plugs; and
a second capping insulating pattern being between the first channel region and the second channel region, overlapping the back gate electrode in the vertical direction, and located between the back gate electrode and the conductive line,
wherein the horizontal extension portion of the back gate dielectric film is between the back gate electrode and one selected from the first capping insulating pattern and the second capping insulating pattern.

5. The semiconductor memory device of claim 1, further comprising:
a first capping insulating pattern being between the first channel region and the second channel region, overlapping the back gate electrode in the vertical direction, and located between the back gate electrode and the plurality of contact plugs,
wherein the plurality of contact plugs comprise a first contact plug connected to the first channel region and a second contact plug connected to the second channel region, and
the horizontal extension portion of the back gate dielectric film is between the first capping insulating pattern and the back gate electrode and is apart from the first and second contact plugs in the vertical direction.

6. The semiconductor memory device of claim 5, wherein the vertical extension portion of the back gate dielectric film is in contact with the conductive line.

7. The semiconductor memory device of claim 1, further comprising:
a capping insulating pattern being between the first channel region and the second channel region, overlapping the back gate electrode in the vertical direction, and located between the back gate electrode and the conductive line,
wherein the horizontal extension portion of the back gate dielectric film is between the capping insulating pattern and the back gate electrode in the vertical direction and is apart from the conductive line in the vertical direction.

8. The semiconductor memory device of claim 7, wherein the plurality of contact plugs comprise a first contact plug connected to the first channel region and a second contact plug connected to the second channel region, and
the vertical extension portion of the back gate dielectric film is in contact with each of the first and second contact plugs.

9. The semiconductor memory device of claim 1, further comprising:
a third channel region apart from the second channel region in the first horizontal direction and configured to be connected to the conductive line;
a pair of word lines each being between the second channel region and the third channel region and apart from each other in the first horizontal direction, the pair of word lines including a first word line relatively closer to the second channel region and a second word line relatively closer to the third channel region;
a first gate dielectric film between the first word line and the second channel region; and
a second gate dielectric film between the second word line and the third channel region,
wherein each of the first gate dielectric film and the second gate dielectric film comprises one end in contact with the conductive line and another end in contact with one contact plug selected from the plurality of contact plugs.

10. The semiconductor memory device of claim 9, wherein the back gate electrode has a first end surface facing the plurality of contact plugs and a second end surface facing the conductive line,
the horizontal extension portion of the back gate dielectric film is apart from the plurality of contact plugs in the vertical direction and is in contact with the second end surface of the back gate electrode, and
a first vertical distance from the plurality of contact plugs to the second end surface of the back gate electrode is greater than a second vertical distance from the plurality of contact plugs to the pair of word lines.

11. The semiconductor memory device of claim 9, wherein the back gate electrode has a first end surface facing the plurality of contact plugs and a second end surface facing the conductive line,
the horizontal extension portion of the back gate dielectric film is apart from the conductive line in the vertical direction and is in contact with the second end surface of the back gate electrode, and
a first vertical distance from the conductive line to the second end surface of the back gate electrode is greater than a second vertical distance from the conductive line to the pair of word lines.

12. A semiconductor memory device comprising:
a conductive line extending lengthwise in a first horizontal direction;
a plurality of channel regions over the conductive line and apart from each other in the first horizontal direction, each of the plurality of channel regions configured to be connected to the conductive line;
a plurality of contact plugs apart from the conductive line in a vertical direction with the plurality of channel regions therebetween, the plurality of contact plugs aligned in the first horizontal direction;
a back gate electrode apart from the conductive line and each of the plurality of contact plugs in the vertical direction, the back gate electrode extending lengthwise in a second horizontal direction between first and second channel regions, the first and second channel regions being two adjacent channel regions selected from the plurality of channel regions, the second horizontal direction being perpendicular to the first horizontal direction;
a first word line apart from the back gate electrode in the first horizontal direction with the first channel region therebetween;
a second word line apart from the back gate electrode in the first horizontal direction with the second channel region therebetween; and
a back gate dielectric film covering surfaces of the back gate electrode,
wherein the back gate dielectric film comprises a vertical extension portion and a horizontal extension portion, the vertical extension portion between the back gate electrode and the first channel region and between the back gate electrode and the second channel region and covering sidewalls of the back gate electrode, the horizontal extension portion integrally connected to the vertical extension portion and covering an end surface of the back gate electrode at one position selected from a first position facing the conductive line and a second position facing the plurality of contact plugs.

13. The semiconductor memory device of claim 12, further comprising:
a first gate dielectric film between the first word line and the first channel region; and
a second gate dielectric film between the second word line and the second channel region,
wherein each of the first gate dielectric film and the second gate dielectric film comprises one end in contact with the conductive line and another end in contact with one contact plug selected from the plurality of contact plugs, and
the back gate dielectric film is apart from the plurality of contact plugs and in contact with the conductive line.

14. The semiconductor memory device of claim 12, further comprising:
a first gate dielectric film between the first word line and the first channel region; and
a second gate dielectric film between the second word line and the second channel region,
wherein each of the first gate dielectric film and the second gate dielectric film comprises one end in contact with the conductive line and another end in contact with one contact plug selected from the plurality of contact plugs,
the plurality of contact plugs comprise a first contact plug connected to the first channel region and a second contact plug connected to the second channel region, and
the back gate dielectric film is apart from the conductive line and in contact with each of the first contact plug and the second contact plug.

15. The semiconductor memory device of claim 12, further comprising:
a first capping insulating pattern being between the first channel region and the second channel region and overlapping the back gate electrode in the vertical direction; and
a first gap-fill insulating pattern overlapping the first word line in the vertical direction,
wherein the plurality of contact plugs comprise a first contact plug connected to the first channel region and a second contact plug connected to the second channel region,
the back gate dielectric film is apart from the first and second contact plugs in the vertical direction with the first capping insulating pattern therebetween,
the first word line is apart from the first contact plug in the vertical direction with the first gap-fill insulating pattern therebetween, and
in the vertical direction, a length of the first capping insulating pattern is greater than a length of the first gap-fill insulating pattern.

16. The semiconductor memory device of claim 12, further comprising:
a first capping insulating pattern being between the first channel region and the second channel region and overlapping the back gate electrode in the vertical direction; and
a first gap-fill insulating pattern overlapping the first word line in the vertical direction,
wherein the back gate dielectric film is apart from the conductive line in the vertical direction with the first capping insulating pattern therebetween,
the first word line is apart from the conductive line in the vertical direction with the first gap-fill insulating pattern therebetween, and
in the vertical direction, a length of the first capping insulating pattern is greater than a length of the first gap-fill insulating pattern.

17. The semiconductor memory device of claim 12, further comprising:
a first capping insulating pattern being between the first channel region and the second channel region and overlapping the back gate electrode in the vertical direction; and
a first gap-fill insulating pattern overlapping the first word line in the vertical direction,
wherein the plurality of contact plugs comprise a first contact plug connected to the first channel region and a second contact plug connected to the second channel region,
the back gate dielectric film is apart from the first and second contact plugs in the vertical direction with the first capping insulating pattern therebetween,
the first word line is apart from the first contact plug in the vertical direction with the first gap-fill insulating pattern therebetween, and
in the vertical direction, a length of the first capping insulating pattern is equal to a length of the first gap-fill insulating pattern.

18. The semiconductor memory device of claim 12, further comprising:
a first capping insulating pattern being between the first channel region and the second channel region and overlapping the back gate electrode in the vertical direction; and
a first gap-fill insulating pattern overlapping the first word line in the vertical direction,
wherein the back gate dielectric film is apart from the conductive line in the vertical direction with the first capping insulating pattern therebetween,
the first word line is apart from the conductive line in the vertical direction with the first gap-fill insulating pattern therebetween, and
in the vertical direction, a length of the first capping insulating pattern is equal to a length of the first gap-fill insulating pattern.

19. The semiconductor memory device of claim 12, wherein each of the end surface of the back gate electrode covered by the horizontal extension portion of the back gate dielectric film and the horizontal extension portion of the back gate dielectric film extends nonlinearly in the first horizontal direction.

20. A semiconductor memory device comprising:
a plurality of conductive lines extending lengthwise in a first horizontal direction and being apart from each other in a second horizontal direction, the second horizontal direction being perpendicular to the first horizontal direction;
a plurality of contact plugs apart from the plurality of conductive lines in a vertical direction;
a plurality of channel regions between the plurality of conductive lines and the plurality of contact plugs, each of the plurality of channel regions comprising one end connected to one conductive line from among the plurality of conductive lines and another end connected to one contact plug selected from the plurality of contact plugs;
a plurality of back gate electrodes apart from each other in the first horizontal direction and extending lengthwise in the second horizontal direction between the plurality of conductive lines and the plurality of contact plugs;
a plurality of back gate dielectric films covering surfaces of the plurality of back gate electrodes, respectively, each of the plurality of back gate dielectric films being in contact with one back gate electrode selected from the plurality of back gate electrodes and with a pair of channel regions adjacent to the one back gate electrode; and
a plurality of word lines extending lengthwise in the second horizontal direction and between the plurality of conductive lines and the plurality of contact plugs,
wherein the plurality of word lines are arranged such that each pair of adjacent word lines selected from the plurality of word lines are between a pair of back gate electrodes selected from among the plurality of back gate electrodes, and
each of the plurality of back gate dielectric films comprises a vertical extension portion and a horizontal extension portion, the vertical extension portion covering sidewalls of a corresponding back gate electrode selected from the plurality of back gate electrodes, the horizontal extension portion integrally connected to the vertical extension portion and covering an end surface of the corresponding back gate electrode at one position selected from a first position facing the plurality of conductive lines and a second position facing the plurality of contact plugs.
